(19) United States
(12) Patent Application Publication
(10) Pub. No.: US 2026/0047142 A1
(43) Pub. Date: Feb. 12, 2026

(54) SEMICONDUCTOR DEVICE AND MANUFACTURING METHOD THEREOF

(71) Applicant: TAIWAN SEMICONDUCTOR MANUFACTURING COMPANY LTD., HSINCHU (TW)

(72) Inventors: YU-CHIEN CHIU, HSINCHU (TW); CHIEN-HAO HUANG, HSINCHU CITY (TW); YA-YUN CHENG, TAICHUNG CITY (TW); WAI-KIT LEE, TUEN MUN, N.T. (HK); WEN-LING LU, TAOYUAN CITY (TW); CHUNG-WEI WU, HSIN-CHU COUNTY (TW); ZHIQIANG WU, HSINCHU COUNTY (TW)

(21) Appl. No.: 18/796,338

(22) Filed: Aug. 7, 2024

(51) Int. Cl. H01L 29/786; H01L 29/417; H01L 29/423; H01L 29/66

(52) U.S. Cl. CPC H10D 30/6755; H10D 30/031; H10D 30/6729; H10D 30/6736

(57) ABSTRACT

The present disclosure provides a semiconductor device and a method of manufacturing a semiconductor device. The semiconductor device includes a drain electrode, a first oxide semiconductor layer, and a gate dielectric layer. The first oxide semiconductor layer is disposed below the drain electrode and has a first surface in contact with the drain electrode. The gate dielectric layer is disposed below the drain electrode and has a second surface in contact with the drain electrode. A first elevation of the first surface is higher than or identical to a second elevation of the second surface.

### BACKGROUND

Electronic equipment involving semiconductor devices is essential for many modern applications. Technological advances in materials and design have produced generations of semiconductor devices, each generation featuring smaller and more complex circuits than the previous generation. The semiconductor integrated circuit (IC) industry has produced a wide variety of digital devices to tackle challenges across various domains. Certain digital devices, such as memory devices, are configured for the storage of data. One promising option for such memory devices involves transistors with oxide semiconductor material known for its inherently high mobility.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features may be arbitrarily increased or reduced for clarity of discussion.

FIG. 1A is a cross-sectional view illustrating a semiconductor device in accordance with some embodiments of the present disclosure.

FIG. 1B is a schematic view illustrating a semiconductor device in accordance with some embodiments of the present disclosure.

FIG. 1C is a schematic diagram illustrating a memory array according to aspects of the present disclosure in one or more embodiments.

FIG. 2 is a cross-sectional view illustrating a semiconductor device in accordance with some embodiments of the present disclosure.

FIG. 3 is a cross-sectional view illustrating a semiconductor device in accordance with some embodiments of the present disclosure.

FIG. 4A is a cross-sectional view illustrating a semiconductor device in accordance with some embodiments of the present disclosure.

FIG. 4B is a schematic view illustrating a semiconductor device in accordance with some embodiments of the present disclosure.

FIGS. 5A, 6A, 7A, 8A, 9A, 10A, 11A, 12A, 13A, and 14A are cross-sectional views of manufacturing a semiconductor device in accordance with some embodiments of the present disclosure.

FIGS. 5B, 6B, 7B, 8B, 9B, 10B, 11B, 12B, 13B, and 14B are schematic views of manufacturing a semiconductor device in accordance with some embodiments of the present disclosure.

FIG. 15 is a flow diagram of a method of manufacturing a semiconductor device in accordance with some embodiments of the present disclosure.

FIG. 16A is a cross-sectional view illustrating a semiconductor device in accordance with some embodiments of the present disclosure.

FIG. 16B is a schematic view illustrating a semiconductor device in accordance with some embodiments of the present disclosure.

FIG. 17 is a cross-sectional view illustrating a semiconductor device in accordance with some embodiments of the present disclosure.

FIGS. 18A, 19A, 20A, 21A, 22A, 23A, 24A, and 25A are cross-sectional views of manufacturing a semiconductor device in accordance with some embodiments of the present disclosure.

FIGS. 18B, 19B, 20B, 21B, 22B, 23B, 24B, and 25B are schematic views of manufacturing a semiconductor device in accordance with some embodiments of the present disclosure.

FIG. 26 is a flow diagram of a method of manufacturing a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device may be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

The present disclosure relates to a semiconductor memory device. The semiconductor memory device includes an oxide semiconductor layer, a gate dielectric layer, a drain electrode, a source electrode, and a gate electrode. The oxide semiconductor layer has a fin shape surrounded by the gate electrode. The interface between the oxide semiconductor layer and the drain electrode and the interface between the gate dielectric layer and the drain electrode are coplanar. The length of the oxide semiconductor layer between the source electrode and the drain electrode is substantially identical to the length of the gate dielectric layer. The present disclosure further relates to a method of manufacturing a semiconductor device. The method includes: forming a sacrificial layer over a source electrode; forming a gate electrode adjacent to the sacrificial layer; removing the sacrificial layer to define a hole; and forming an oxide semiconductor in the hole. The oxide semiconductor layer is formed after the gate electrode and thus undergoes less damage. The quality of the oxide semiconductor layer and the reliability of the semiconductor device can be improved.

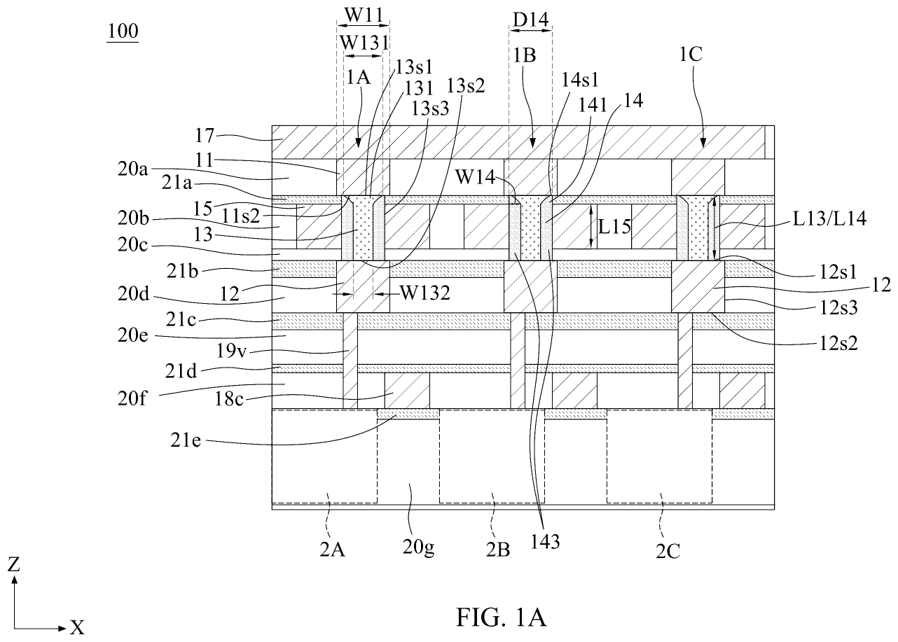

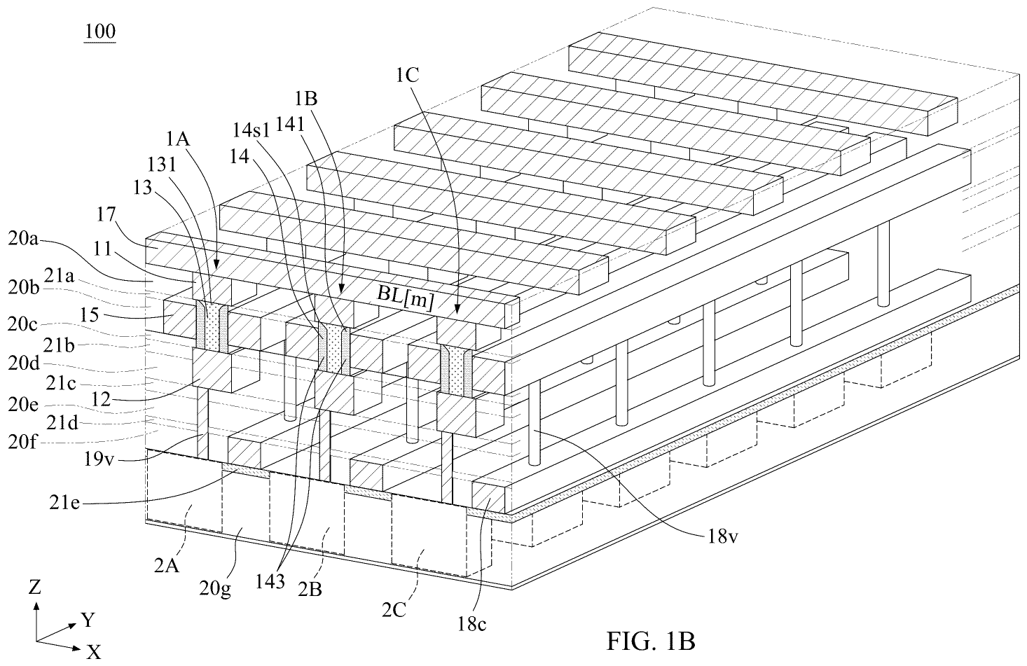

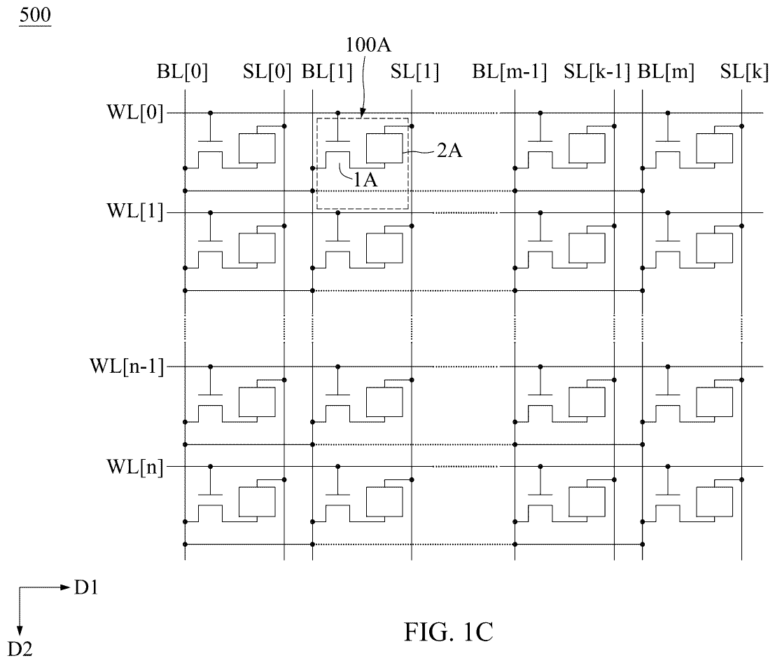

FIG. 1A is a cross-sectional view illustrating a semiconductor device 100 in accordance with some embodiments of the present disclosure. FIG. 1B is a schematic view illustrating the semiconductor device 100 in accordance with some embodiments of the present disclosure.

The semiconductor device 100 may include transistors 1A, 1B, and 1C and memory elements 2A, 2B, and 2C. The transistors 1A, 1B, and 1C respectively correspond to the memory elements 2A, 2B, and 2C. The transistors 1A, 1B, and 1C respectively connect to the memory elements 2A, 2B, and 2C. The semiconductor device 100 may be a semiconductor memory device. The semiconductor device 100 may include a plurality of memory cells, each of which includes one transistor and the corresponding memory element. The transistors 1A, 1B, and 1C are switches. When the transistors 1A, 1B, and 1C turn on in response to the control voltage from the word lines of the semiconductor device 100, the data stored in the corresponding memory element may be accessed or the corresponding memory element may be written. When the transistors 1A, 1B, and 1C turn off, the memory elements are disconnected from the bit lines of the semiconductor device 100.

The semiconductor device 100 may include DRAM, MRAM, RRAM, PCRAM, and ferroelectric tunnel junction (FTJ) memory. The transistors 1A, 1B, and 1C may serve as selectors for the memory elements 2A, 2B, and 2C. The memory elements 2A, 2B, and 2C may include DRAM elements (e.g., capacitors), MRAM elements (e.g., a magnetic tunneling junction (MTJ) element), RRAM elements, PCRAM elements, FTJ elements, or capacitors.

The transistors 1A, 1B, and 1C may each include a thin film transistor. The transistors 1A, 1B, and 1C may each include an oxide semiconductor thin film transistor. The transistors 1A, 1B, and 1C may each include a three-dimensional (3D) oxide semiconductor thin film transistor. Owing to the profile of the channel, the transistors 1A, 1B, and 1C may be called fin transistors.

Each of the transistors 1A, 1B, and 1C includes a gate electrode, a drain electrode, and a source electrode. In the present disclosure, the terms “gate electrode” and “gate” are interchangeable; the terms “drain electrode” and “drain” are interchangeable; and the terms “source electrode” and “source” are interchangeable.

The semiconductor device 100 includes a drain electrode 11, a source electrode 12, an oxide semiconductor layer 13, a gate dielectric layer 14, a gate electrode 15, a conductive trace 17, a conductive via 18v, a conductive trace 18c, a conductive via 19v, a plurality of insulating layers 20a, 20b, 20c, 20d, 20c, 20f, and 20g, and a plurality of passivation layers 21a, 21b, 21c, 21d, and 21c.

The transistor 1A includes the drain electrode 11, the source electrode 12, the oxide semiconductor layer 13, the gate dielectric layer 14, and the gate electrode 15. The transistors 1B and 1C may each include structures/components identical to those of the transistor 1A.

The drain electrode 11 is surrounded by the insulating layer 20a. The drain electrode 11 is disposed below the conductive trace 17. The drain electrodes 11 of each of the transistors 1A, 1B, and 1C are connected to the conductive trace 17. The drain electrode 11 is disposed on the passivation layer 21a. The drain electrode 11 is disposed over the gate electrode 15, the oxide semiconductor layer 13, the gate dielectric layer 14, and/or the source electrode 12.

The drain electrodes 11 of each of the transistors 1A, 1B, and 1C arranged along the X direction may be separated from each other. Furthermore, in the schematic view of FIG. 1B, the drain electrodes 11 of each of the transistors 1A, 1B, and 1C may be separated from other transistors arranged along the Y direction. In FIG. 1B, the conductive trace 17 is indicated as a bit line BL[m] that is shared by the transistors arranged along the X direction.

The drain electrode 11 has a bottom surface 11s2 facing the oxide semiconductor layer 13. In some embodiments, the bottom surface 11s2 may be in contact with the oxide semiconductor layer 13 and/or the gate dielectric layer 14. The drain electrode 11 may include a seed layer (not shown) disposed at the bottom surface 11s2 of the drain electrode 11.

In some embodiments, the material of the drain electrode 11 may include tungsten (W), molybdenum (Mo), ruthenium (Ru), tantalum nitride (TaN), titanium nitride (TiN), cobalt (Co), copper (Cu), aluminum (Al), indium tin oxide (ITO) or alloys thereof. In some embodiments, the material of the drain electrode 11 may include silicon, germanium, or the like. In some embodiments, the material of the seed layer may include tantalum nitride (TaN), titanium nitride (TiN), copper (Cu), or the like.

The source electrode 12 is surrounded by the insulating layer 20d. The source electrode 12 is disposed on the passivation layer 21c. The source electrode 12 is disposed below the drain electrode 11, the oxide semiconductor layer 13, the gate dielectric layer 14, and/or the gate electrode 15. The source electrodes 12 of each of the transistors 1A, 1B, and 1C arranged along the X direction may be separated from each other. Furthermore, in the schematic view of FIG. 1B, the source electrodes 12 of each of the transistors arranged along the Y direction may be separated from each other. The source electrodes 12 of each of the transistors 1A, 1B, and 1C are connected to the corresponding ones of the memory elements 2A, 2B, and 2C through the conductive via 19v.

The conductive via 19v is disposed between the transistor 1A and the memory element 2A. The conductive via 19v may include a seed layer disposed along the bottom and sidewall of the conductive via 19v. The conductive via 19v may extend through the passivation layers 21d and 21e and the insulating layers 20e and 20f to connect the memory element 2A, 2B, or 2C. The memory elements 2A, 2B, and 2C may be surrounded by the insulating layer 20g.

The source electrode 12 has a top surface 12s1 facing the oxide semiconductor layer 13 and the gate dielectric layer 14, a bottom surface 12s2 facing the memory element 2A, and a lateral surface 12s3 connecting the top surface 12s1 to the bottom surface 12s2. The source electrode 12 may include a seed layer (not shown) disposed at the bottom surface 12s2 of the source electrode 12.

In some embodiments, the material of the source electrode 12 may include tungsten (W), molybdenum (Mo), ruthenium (Ru), tantalum nitride (TaN), titanium nitride (TiN), cobalt (Co), copper (Cu), aluminum (Al), indium tin oxide (ITO) or alloys thereof. In some embodiments, the material of the source electrode 12 may include silicon, germanium, or the like. In some embodiments, the material of the seed layer may include tantalum nitride (TaN), titanium nitride (TiN), copper (Cu), or the like.

In some embodiments, the material of the conductive via 19v may include tungsten (W), tantalum nitride (TaN), titanium nitride (TiN), cobalt (Co), copper (Cu), aluminum (Al), or the like. In some embodiments, the material of the seed layer 19g may include tantalum nitride (TaN), titanium nitride (TiN), copper (Cu), or the like.

The gate electrode 15 is surrounded by the insulating layer 20b. The gate electrodes 15 of each of the transistors 1A, 1B, and 1C are separated from each other by the insulating layer 20b. The gate electrode 15 is disposed over the insulating layer 20c. The gate electrode 15 is in contact with the insulating layer 20c. The gate electrode 15 is disposed below the passivation layer 21a. The gate electrode 15 is disposed between the drain electrode 11 and the source electrode 12 in the Z direction. The gate electrode 15 surrounds the gate dielectric layer 14 and/or the oxide semiconductor layer 13.

In some embodiments, the material of the gate electrode 15 may include tungsten (W), tantalum nitride (TaN), titanium nitride (TiN), aluminum (Al), or alloys thereof. In some embodiments, the material of the gate electrode 15 may include silicon, germanium, or the like.

The conductive trace (or the word line trace) 18c is disposed below the source electrode 12. The word line trace 18c is surrounded by the insulating layer 20f. The word line trace 18c is disposed between the passivation layers 21d and 21e. The passivation layer 21e is disposed between the memory elements 2A, 2B, and 2C. The conductive via (or the word line via) 18v connects the word line trace 18c to the gate electrode 15. The word line trace 18c is disposed below and connected to the word line via 18v. The word line trace 18c is connected to the gate electrode 15. The word line trace 18c is indicated as a word line WL[n] as shown in FIG. 1B. The word line via 18v and the word line trace 18c may include a seed layer (not shown). The seed layer may be formed to facilitate the deposition of the word line via 18v and the word line trace 18c. The seed layer may be disposed along the bottom and sidewall of the word line via 18v and along the bottom of the word line trace 18c.

In some embodiments, the material of the word line via 18v and the word line trace 18c may include tungsten (W), tantalum nitride (TaN), titanium nitride (TiN), cobalt (Co), copper (Cu), aluminum (Al), or the like. In some embodiments, the material of the seed layer 18g may include tantalum nitride (TaN), titanium nitride (TiN), copper (Cu), or the like.

In some embodiments, the material of the passivation layers 21a, 21b, 21c, 21d, and 21e may include aluminum oxide (AlO) or the like. In some embodiments, the insulating layers 20a, 20b, 20c, 20d, 20c, 20f, and 20g may be formed of low-K dielectric material. In some embodiments, the insulating layers 20a, 20b, 20c, 20d, 20c, 20f, and 20g include materials such as spin-on dielectric (SOD), spin-on glass, spin-on polymers, silicon carbon material, un-doped silicate glass, or doped silicon oxide such as phosphor-silicate glass (PSG), borophosphosilicate glass (BPSG), fluorinated silicate glass (FSG), compounds thereof, composites thereof, combinations thereof, and/or other suitable dielectric materials. In some embodiments, the insulating layers 20a, 20b, 20c, 20d, 20c, 20f, and 20g may include silicon oxide (SiO), but the disclosure is not limited thereto.

The gate dielectric layer 14 is surrounded by the gate electrode 15. The gate dielectric layer 14 is not disposed between the source electrode 12 and the insulating layer 20c. The gate dielectric layer 14 is in contact with the source electrode 12. The gate dielectric layer 14 is in contact with the drain electrode 11. The gate dielectric layer 14 is disposed below the drain electrode 11 and has a surface 14s1 in contact with the drain electrode 11. In some embodiments, the gate dielectric layer 14 may be spaced apart from the drain electrode 11 by the oxide semiconductor layer 13. The gate dielectric layer 14 may have a portion 141 adjacent to the drain electrode 11. The portion 141 is tapered toward the drain electrode 11. The portion 141 may have a width W14 that gradually decreases in a direction toward the drain electrode 11 (or in the Z direction). The gate dielectric layer 14 has two lateral portions 143 from a cross-sectional view. A distance D14 between the two lateral portions 143 is smaller than a width W11 of the drain electrode 11. One of the lateral portions 143 has multiple thicknesses.

In some embodiments, the gate dielectric layer 14 includes a high-k dielectric material having a high dielectric constant. The high-K dielectric material may include hafnium dioxide (HfO₂), zirconium dioxide (ZrO₂), aluminum oxide (Al₂O₃), lanthanum oxide (La₂O₃), titanium oxide (TiO₂), yttrium oxide (Y₂O₃), strontium titanate (SrTiO₃), hafnium oxynitride (HfOₓN_{y}), hafnium silicate, zirconium silicate, other suitable metal-oxides, metal silicates, or combinations thereof. The gate dielectric layer 14 may include silicon dioxide, silicon oxynitride.

The oxide semiconductor layer 13 is surrounded by the gate dielectric layer 14. The oxide semiconductor layer 13 may have a fin profile in the Y direction. In some embodiments, a channel region may be formed in the oxide semiconductor layers 13 in response to the voltage applied between the gate electrode 15 and the source electrode 12. Such a channel region connects the drain electrode 11 to the source electrode 12.

The oxide semiconductor layers 13 of each of the transistors 1A, 1B, and 1C arranged along the X direction may be separated from each other. Furthermore, in the schematic view of FIG. 1B, the oxide semiconductor layers 13 of each of the transistors 1A, 1B, and 1C may be separated from other transistors arranged along the Y direction.

In some embodiments, the oxide semiconductor layer 13 may include an oxide semiconductor material, such as indium zinc oxide (IZO), indium-gallium-zinc oxide (IGZO), zinc oxide (ZnO), indium oxide (InO), stannous oxide (SnO), copper oxide (CuO), nickel oxide (NiO), copper aluminum oxide, copper gallium oxide (CGO), copper indium oxide, strontium copper oxide (SCO), or the like, but is not limited to the above-mentioned materials.

The oxide semiconductor layer 13 is disposed below the drain electrode 11 and has a surface (or a top surface) 13s1 in contact with the drain electrode 11. The oxide semiconductor layer 13 is disposed over the source electrode 12 and has a surface (or a bottom surface) 13s2 in contact with the source electrode 12. A first width W131 of the top surface 13s1 is larger than a second width W132 of the bottom surface 13s2. The ratio of the second width W132 and the first width W131 may be around 0.5. In some embodiments, the range of the ratio may be greater than 0.4 and smaller than 1. The taper profile of the gate dielectric layer 14 induces the difference (or the ratio) of the second width W132 and the first width W131. The oxide semiconductor layer 13 has a lateral surface 13s3 connecting the top surface 13s1 to the bottom surface 13s2. At least one of the lateral portions 143 of the gate dielectric layer 14 is in contact with the lateral surface 13s3 of the oxide semiconductor layer 13.

In some cases, the formation of a transistor includes forming an oxide semiconductor layer prior to forming a gate electrode, wherein the gate electrode surrounds the oxide semiconductor layer. A sacrificial layer may remain over the oxide semiconductor layer and be subsequently removed after the gate electrode is formed. Thus, a length of the oxide semiconductor layer may be shorter than a length of the gate electrode. This is called the “oxide semiconductor layer missing effect” in the present disclosure. The actual characteristics of a transistor may have deviate from its defined specifications.

In the present disclosure, the gate electrode 15 is formed prior to the formation of the oxide semiconductor layer 13. The gate electrode 15 surrounds a sacrificial layer which is then removed to define a region (or a hole), and the oxide semiconductor layer 13 is formed in the hole. A first height (or length) L13 of the oxide semiconductor layer 13 is greater than or equal to a second height (or length) L14 of the gate dielectric layer 14. Furthermore, the first height L13 of the oxide semiconductor layer 13 is greater than a third height (or length) L15 of the gate electrode 15. The oxide semiconductor layer missing effect can be prevented.

Additionally, the oxide semiconductor layer 13 is formed within the hole surrounded by the gate electrode 15. The oxide semiconductor layer 13 has fewer defects than an oxide semiconductor layer formed by blanket deposition of an oxide semiconductor material and subsequent etching. The quality of oxide semiconductor layer 13 and the reliability of the semiconductor device 100 can be improved.

In some embodiments, the oxide semiconductor layer 13 has a top portion 131 in contact with the drain electrode 11. The top portion 131 has a funnel shape. The top portion 131 of the oxide semiconductor layer 13 is surrounded by the portion 131 of the gate dielectric layer 14. The long side of the funnel shape of the top portion 131 is in contact with the drain electrode 11. The funnel shape of the top portion 131 comes from the taper profile of the portion 141 of the gate dielectric layer 14. In some embodiments, a first elevation of the surface 13s1 of the oxide semiconductor layer 13 is higher than or identical to a second elevation of the surface 14s1 of the gate dielectric layer 14. An interface between the oxide semiconductor layer 13 and the drain electrode 11 and an interface between the gate dielectric layer 14 and the drain electrode 11 may be coplanar.

In some embodiments, the transistor 1A may serve as a selector for the memory element 2A. FIG. 1C is a schematic diagram illustrating a memory array 500 according to aspects of the present disclosure in one or more embodiments.

Referring to FIG. 1C, the memory array 500 includes a plurality of memory elements and a plurality of transistors. In some embodiments, the transistors are configured to access the corresponding memory elements. The transistor 1A is included in the plurality of transistors and the memory element 2A is included in the plurality of memory elements. In some embodiments, the memory array 500 includes a plurality of memory units. A memory unit 100A thereof includes the transistor 1A and the memory element 2A. The plurality of memory units may each include similar or identical components to those of the memory unit 100A. In some embodiments, the memory unit 100A may be a DRAM unit, a RRAM unit, a MRAM unit, a PCRAM unit, a FTJ memory unit.

The memory array 500 further includes bit lines BL, word lines WL and supply lines SL. The bit lines BL are labeled BL[0] through BL[m] in a first direction D1, the word lines are labeled WL[0] through WL[n] in a second direction D2, and the supply lines SL are labeled SL[0] through SL[k] in the first direction D1. The second direction D2 is substantially perpendicular to the first direction D1. The bit line BL is electrically coupled to the drain electrodes of the corresponding transistor (e.g., the bit line BL[1] is electrically coupled to the drain electrode of the transistor 1A). In some embodiments, a single bit line BL is coupled to a number of transistors in the second direction D2.

The supply line SL is electrically coupled to the corresponding memory element (e.g., the supply line SL[1] is electrically coupled to the memory element 2A). In some embodiments, a single supply line SL is coupled to a number of memory elements in the second direction D2. A supply voltage (or a reference voltage or ground) may be applied to the memory element 2A through the supply line SL[1].

The word line WL is electrically coupled to the corresponding transistor (e.g., the word line WL is electrically coupled to the transistor 1A). In some embodiments, a single word line WL is coupled to a number of transistors in the first direction D1. In some embodiments, application of a suitable word line WL voltage to the gate electrode of the transistor 1A controls the state of the transistor 1A. When the transistor 1A turns on in response to the voltage from the word line WL[0], the data stored in the memory element 2A may be accessed or the memory element 2A may be written through the bit line BL[1]. When the transistor 1A turns off, the memory element 2A is disconnected from the bit line BL[1].

The gate electrode of the transistor 1A may be electrically connected to the word line WL, such as the word line WL[0]. The source electrode of the transistor 1A may be electrically connected to the memory element 2A. The drain electrode of the transistor 1A may be electrically connected to the bit line BL, such as the bit line BL[1].

The semiconductor device 100 may undergo further processes to form various features such as contacts/vias, interconnect metal layers, dielectric layers, passivation layers, etc. In some embodiments, prior to the formation of the semiconductor device 100, a FEOL circuit level may be formed. In some embodiments, the semiconductor device 100 may be embedded in the BEOL circuit level.

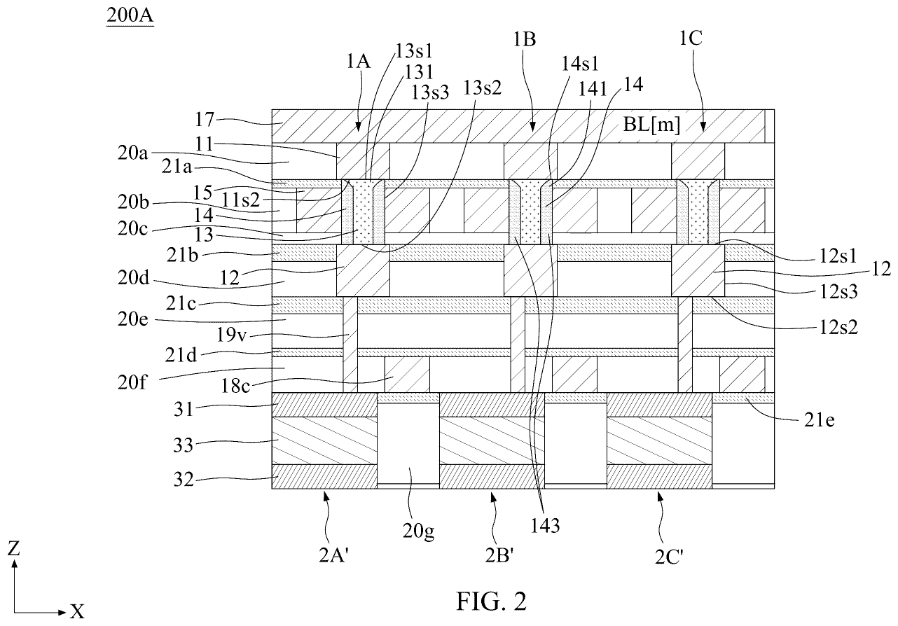

FIG. 2 is a cross-sectional view illustrating a semiconductor device 200A in accordance with some embodiments of the present disclosure. The structure of the semiconductor device 200A is similar to the structure of the semiconductor device 100. Therefore, some detailed descriptions may refer to corresponding preceding paragraphs and are not repeated hereinafter for conciseness, with differences therebetween as follows.

The semiconductor device 200A includes memory elements 2A′, 2B′, and 2C′, each of which includes a sandwiched structure including a first layer 31, a second layer 32, and an intermediate layer 33 sandwiched between the first layer 31 and the second layer 32. The first layer 31 may be connected to the source electrode 12 of each of the transistors 1A, 1B, and 1C. The first layer 34 may be connected to the conductive via 19v. The second layer 32 may be connected to the supply line SL as shown in FIG. 1C.

In some embodiments, the semiconductor device 200A may include DRAM. The sandwiched structure may be a capacitor for the data storage. The first layer 31 and the second layer 32 may be electrically conductive. The intermediate layer 33 may be electrically insulative. The number of charges stored in the capacitor represents the data, such as logic high (“1”) or logic low (“0”). The transistor 1A may be turned on to connect the memory element 2A′ to the bit line BL (or the drain electrode 11). The data of the capacitor may be accessed or written.

In some embodiments, the semiconductor device 200A may include RRAM. The first layer 31 and the second layer 32 may be electrically conductive. The intermediate layer 33 may be electrically insulative. The intermediate layer 33 may be metal oxide. The resistance of the intermediate layer 33 may have multiple states of electrical resistance, each of which represents the stored data, such as logic high (“1”) or logic low (“0”). The transistor 1A may be turned on to connect the memory element 2A′ to the bit line BL (or the drain electrode 11). The data (or the state) of the sandwiched structure may be accessed or written.

In some embodiments, the semiconductor device 200A may include MRAM. The first layer 31 and the second layer 32 may be ferromagnetic. The intermediate layer 33 may be a tunneling barrier layer. The intermediate layer 33 may be metal oxide. The memory element 2A′ can be switched between two states of electrical resistance, i.e., a first state with a low resistance (wherein magnetization directions of the first layer 31 and the second layer 32 are parallel) and a second state with a high resistance (wherein magnetization directions of the first layer 31 and the second layer 32 are antiparallel), to store data. The transistor 1A may be turned on to connect the memory element 2A′ to the bit line BL (or the drain electrode 11). The data (or the state) of the sandwiched structure may be accessed or written.

In some embodiments, the semiconductor device 200A may include PCRAM. The first layer 31 and the second layer 32 may be electrically conductive. The intermediate layer 33 may include chalcogenide glass. The phase of the chalcogenide glass may be switched between amorphous (high resistance) and crystalline (low resistance). The phase represents the data, such as logic high (“1”) or logic low (“0”). The transistor 1A may be turned on to connect the memory element 2A′ to the bit line BL (or the drain electrode 11). The data of the capacitor may be accessed or written.

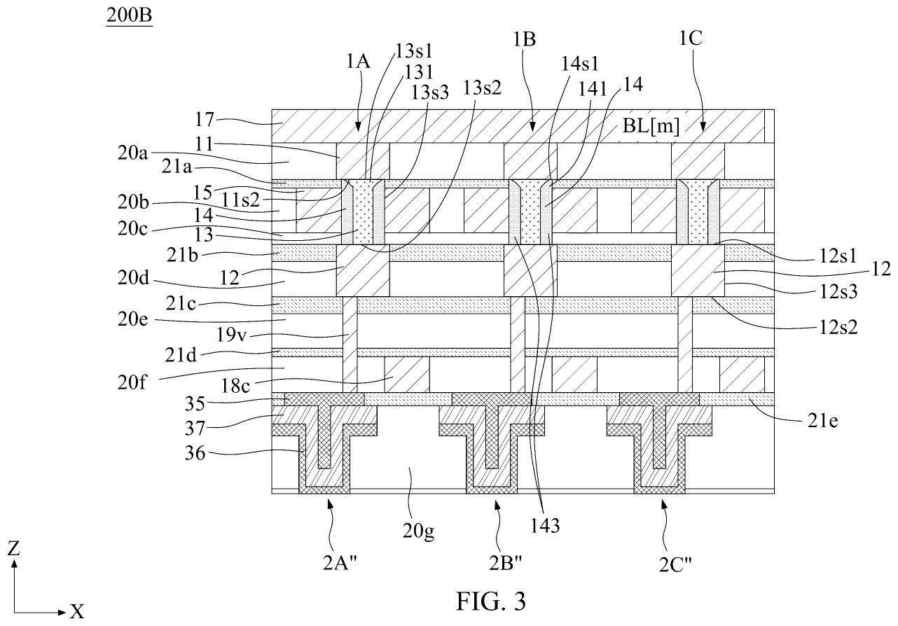

FIG. 3 is a cross-sectional view illustrating a semiconductor device in accordance with some embodiments of the present disclosure. The structure of the semiconductor device 200B is similar to the structure of the semiconductor device 100. Therefore, some detailed descriptions may refer to corresponding preceding paragraphs and are not repeated hereinafter for conciseness, with differences therebetween as follows.

The semiconductor device 200B includes memory elements 2A″, 2B″, and 2C″, each of which includes a 3D metal-insulator-metal (MIM) structure. The 3D MIM structure includes a first layer 35, a second layer 36, and a dielectric layer 37 disposed between the first layer 35 and the second layer 36. The first layer 35 may be connected to the source electrode 12 of each of the transistors 1A, 1B, and 1C. The first layer 35 may be connected to the conductive via 19v. The second layer 36 may be connected to the supply line SL as shown in FIG. 1C.

The first layer 35 may include a vertical portion extending along the X direction and a horizontal portion extending along the Z direction. The second layer 36 may include a vertical portion extending along the X direction and a horizontal portion extending along the Z direction. The vertical portion of the first layer 35 is disposed in a hole defined by the vertical portion of the second layer 36. The horizontal portion of the first layer 35 is disposed over the horizontal portion of the second layer 36.

The dielectric layer 37 may have a topography conforming to the second layer 36. In other words, the dielectric layer 37 may have a portion conformal to the vertical portion of the second layer 36 and a further portion conformal to the horizontal portion of the second layer 36.

The 3D MIM structure as shown in FIG. 3 may be a capacitor. The 3D MIM structure of FIG. 3 may have higher capacitance than the sandwich structure of FIG. 2.

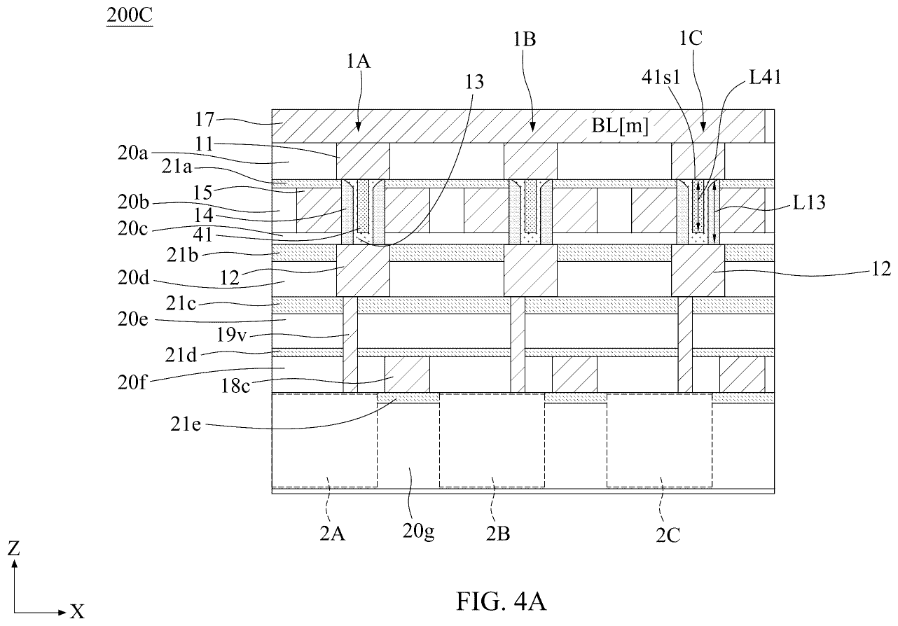

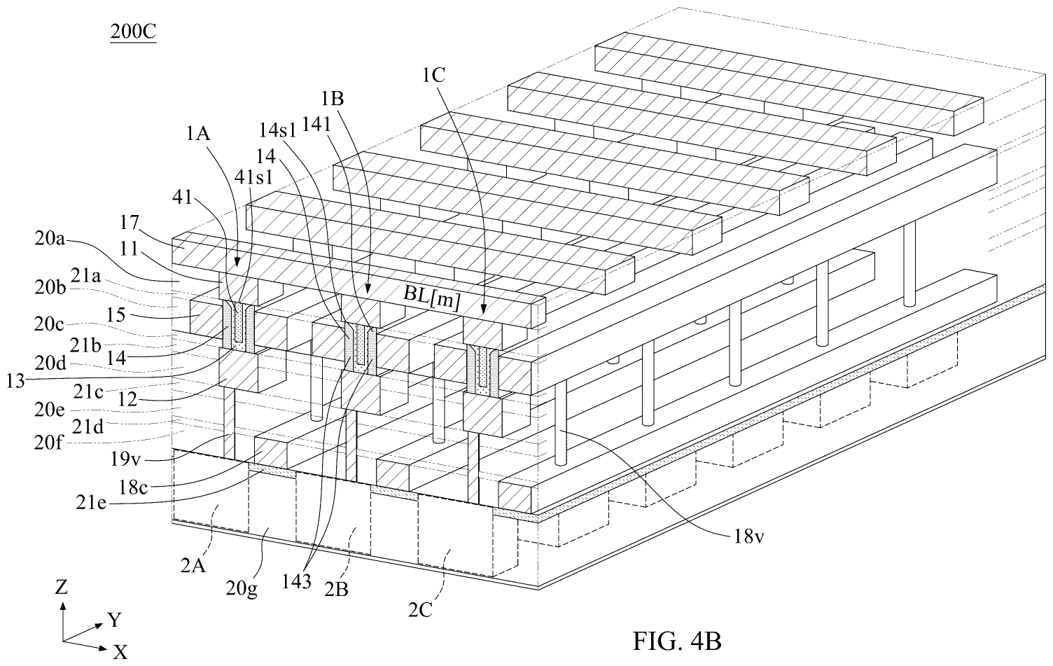

FIG. 4A is a cross-sectional view illustrating a semiconductor device 200C in accordance with some embodiments of the present disclosure. FIG. 4B is a schematic view illustrating the semiconductor device 200C in accordance with some embodiments of the present disclosure. The structure of the semiconductor device 200C is similar to the structure of the semiconductor device 100. Therefore, some detailed descriptions may refer to corresponding preceding paragraphs and are not repeated hereinafter for conciseness, with differences therebetween as follows.

The semiconductor device 200C includes a second oxide semiconductor layer 41 surrounded by the oxide semiconductor layer 13. The second oxide semiconductor layer 41 has a short side 41s1 in contact with the drain electrode 11. The height L13 of the oxide semiconductor layer 13 is greater than a second height L41 of the second oxide semiconductor layer 41.

A first doping concentration of the second oxide semiconductor layer 41 is smaller than a second doping concentration of the oxide semiconductor layer 13. The first doping concentration of the second oxide semiconductor layer 41 may be around 10¹⁵˜10¹⁷ cm⁻³. The second doping concentration of the oxide semiconductor layer 13 may be around 10¹⁷˜10¹⁹ cm⁻³. The thickness of the oxide semiconductor layer 13 may be around 0.5˜100 nm. The thickness of the second oxide semiconductor layer 41 may be around 0.5˜100 nm. The thickness is equal to or greater than 0.5 nm to form a reliable film. The thickness is equal to or less than 100 nm to ensure the quality of the film formed by the ALD process. The second oxide semiconductor layer 41 with lower doping concentration may increase the threshold voltage of the transistor 1A. The multiple oxide semiconductor layers 13 and 41 can reduce the charge traps formed at the interface between the gate dielectric layer 14 and the multiple oxide semiconductor layers 13 and 41. The second oxide semiconductor layer 41 can improve the negative bias temperature instability (NBTI) and/or the positive bias temperature instability (PBTI).

In some embodiments, the second oxide semiconductor layer 41 may include an oxide semiconductor material, such as indium zinc oxide (IZO), indium-gallium-zinc oxide (IGZO), zinc oxide (ZnO), indium oxide (InO), stannous oxide (SnO), copper oxide (CuO), nickel oxide (NiO), copper aluminum oxide, copper gallium oxide (CGO), copper indium oxide, strontium copper oxide (SCO), or the like, but is not limited to the above-mentioned materials. The dopant of the second oxide semiconductor layer 41 and the oxide semiconductor layer 13 may be the same, while the proportions of elements are different, e.g., the proportion of Indium of the oxide semiconductor layer 13 may be larger than that of the second oxide semiconductor layer 41.

FIGS. 4A and 4B show two oxide semiconductor layers surrounded by the gate dielectric layer 14. However, embodiments of the present disclosure are not limited thereto. Many variations and/or modifications can be made to embodiments of the present disclosure. In some embodiments, the number of oxide semiconductor layers can be more than two. There may be multiple oxide semiconductor layers with a U-shape. The concentration of the multiple oxide semiconductor layers gradually decreases from the outermost oxide semiconductor layer to the innermost oxide semiconductor layer. In some embodiments, the concentration of the multiple oxide semiconductor layers gradually decreases in the Z direction from the bottom to the top.

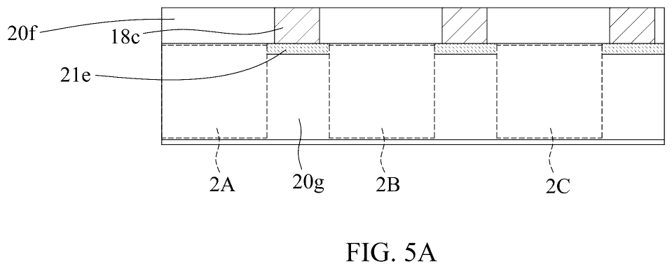

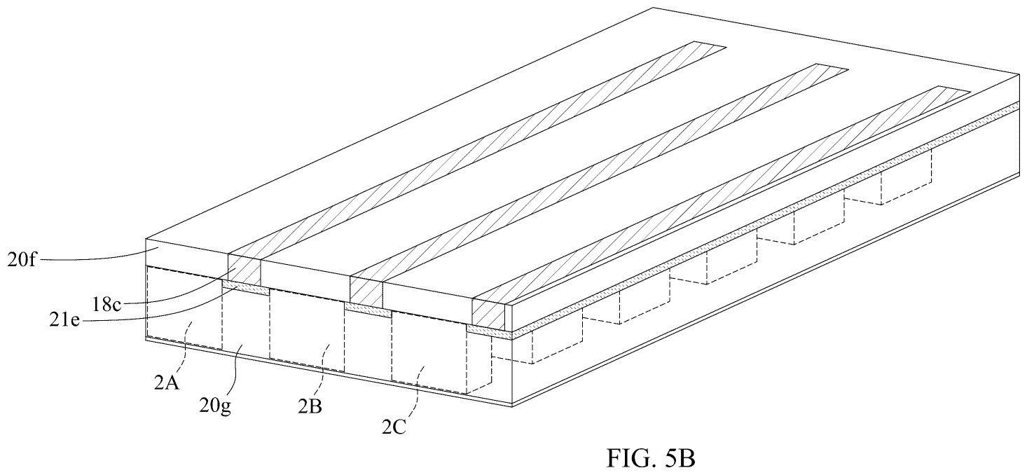

FIGS. 5A, 6A, 7A, 8A, 9A, 10A, 11A, 12A, 13A, and 14A are cross-sectional views of manufacturing a semiconductor device (e.g., the semiconductor device 100) in accordance with some embodiments of the present disclosure. FIGS. 5B, 6B, 7B, 8B, 9B, 10B, 11B, 12B, 13B, and 14B are schematic views of manufacturing a semiconductor device (e.g., the semiconductor device 100) in accordance with some embodiments of the present disclosure.

In FIGS. 5A to 14A and 5B to 14B, similar reference numerals will be assigned to corresponding portions described above, avoiding redundant descriptions. In addition, portions for which no particular description is made have constructions similar to those of semiconductor device 100 described above, and provide the same advantages.

In FIGS. 5A and 5B, a plurality of memory elements (including the memory elements 2A, 2B, and 2C) may be formed in an insulating layer 20g. The memory elements may be spaced apart from each other. A passivation layer 21e may be formed over the insulating layer 20c. An insulating layer 20f may be formed over the insulating layer 20g. A conductive trace 18c may be formed in a trench defined by the insulating layer 20f. The conductive trace 18c is free from overlapping the memory elements in the Z direction. A seed layer (not shown) may be formed along the bottom of the conductive trace 18c.

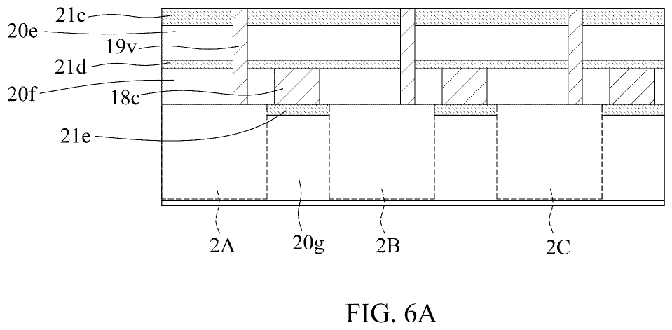

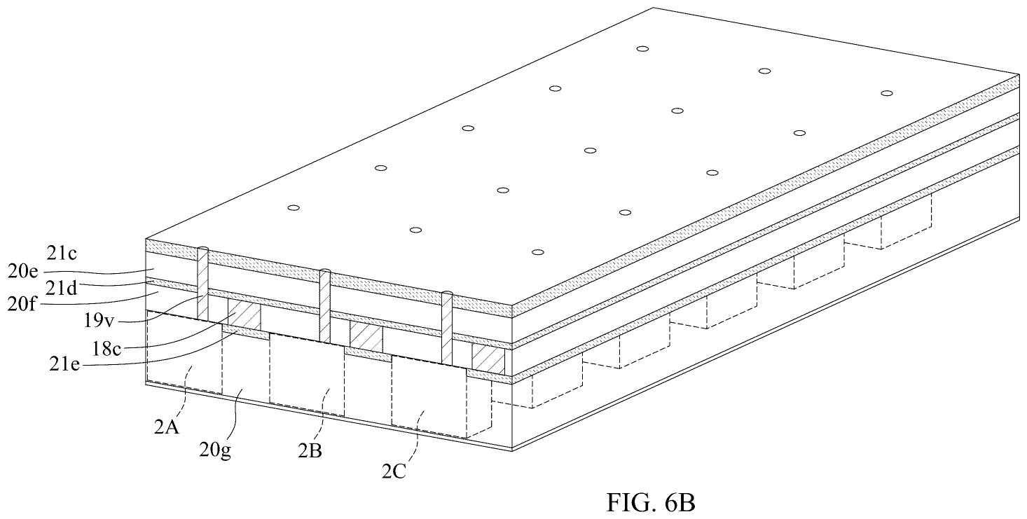

In FIGS. 6A and 6B, a passivation layer 21d, an insulating layer 20c, and a passivation layer 21c may be formed over the insulating layer 21f in sequence. A conductive via 19v may be formed in a hole defined by the passivation layer 21d, the insulating layer 20c, the passivation layer 21c, and the insulating layer 20f to connect each of the memory elements 2A, 2B, and 2C. A seed layer may be formed along the bottom and sidewall of the conductive via 19v.

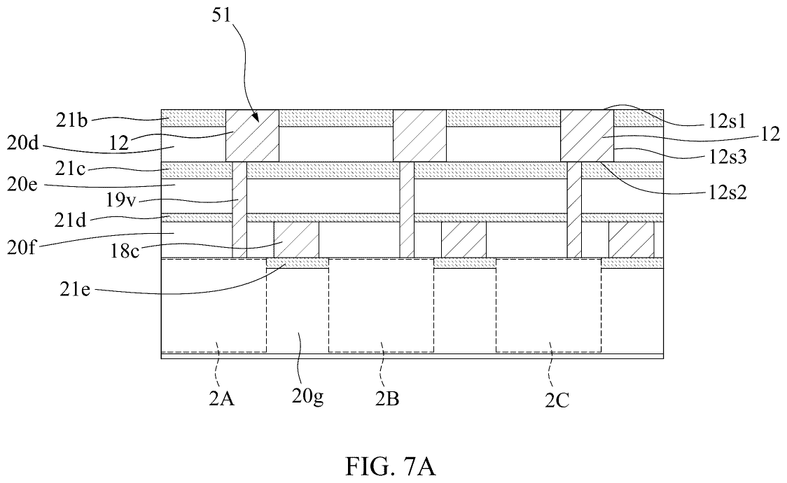

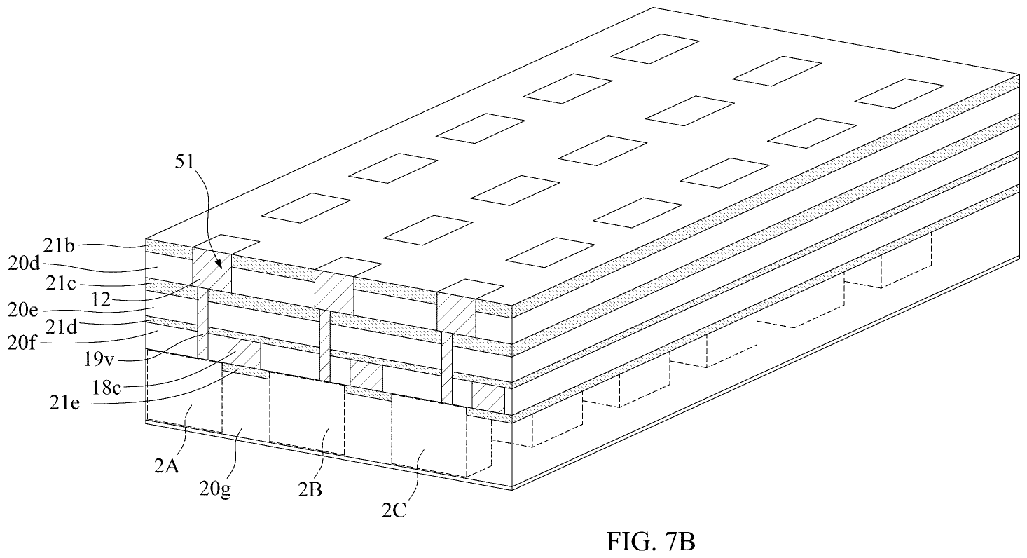

In FIGS. 7A and 7B, an insulating layer 20d and a passivation layer 21b may be formed over the passivation layer 21c in sequence. The insulating layer 20d and the passivation layer 21b may be etched to have a plurality of holes 51, which are separated from each other. A source electrode 12 may be formed in the holes 51. The source electrode 12 may include a seed layer disposed along the bottom and/or the sidewall.

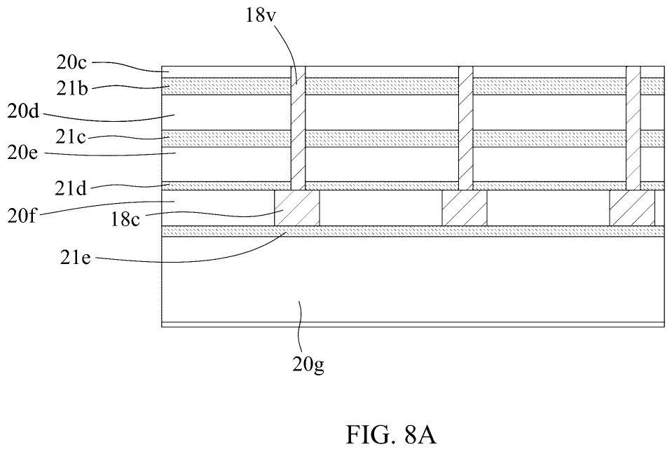

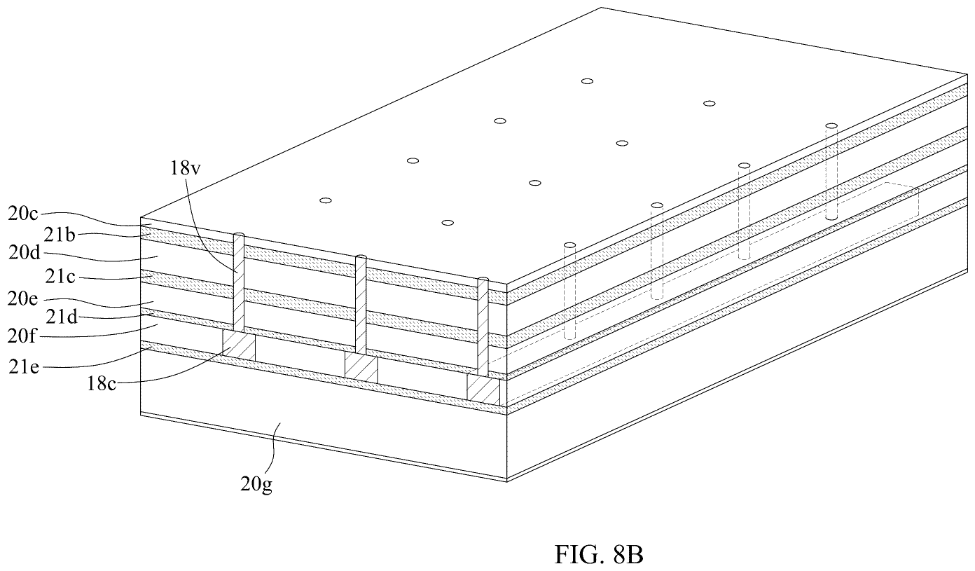

In FIGS. 8A and 8B, an insulating layer 20c may be formed over the passivation layer 21c. FIGS. 8A and 8B are views taken from a position that is different from other figure in the process flow of this embodiment. The insulating layer 20c may be formed over the source electrode 12, which is not shown in the cross-sectional of FIG. 8A. A conductive via 18v may be formed in a hole defined by the insulating layer 20c, the passivation layer 21b, the insulating layer 20d, the passivation layer 21c, the insulating layer 20e, and the passivation layer 21d to connect the conductive trace 18c.

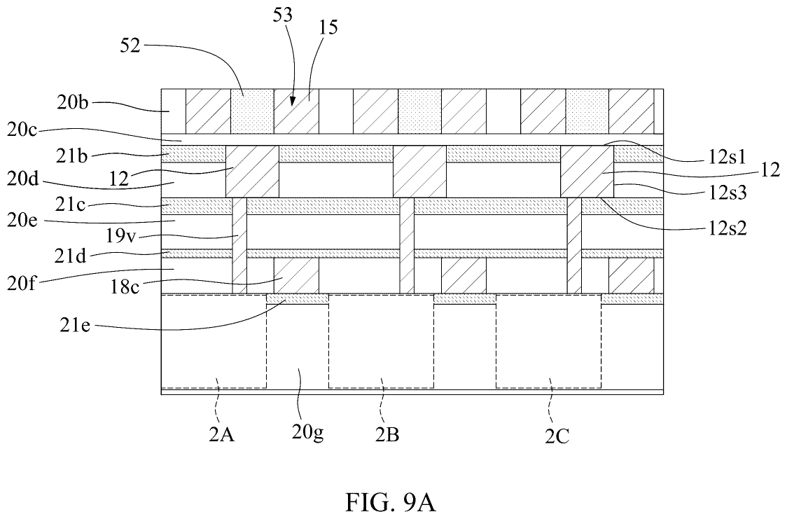

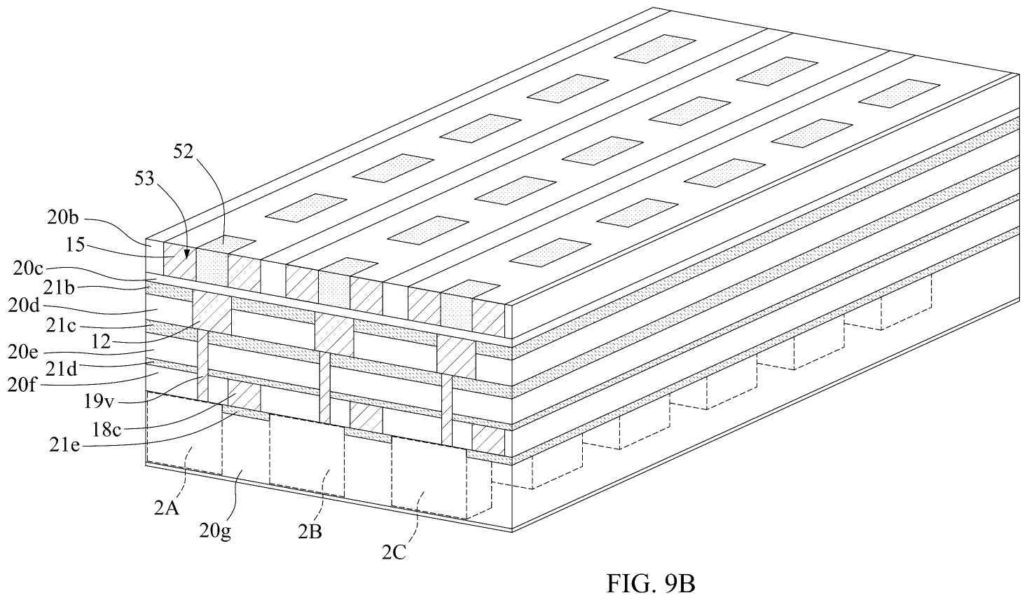

In FIGS. 9A and 9B, an insulating layer 20b is formed over the insulating layer 20c. A sacrificial layer 52 may be formed over the insulating layer 20c. The sacrificial layer 52 may be surrounded by the insulating layer 20b. The sacrificial layer 52 may be etched to define a region 53. The region 53 may overlap the word line trace 18c in the Z direction. A gate electrode 15 is formed in the region 53. The gate electrode 15 may surround the remaining sacrificial layer 52. The material of the sacrificial layer 52 may include SiN, SiCN, SiCON, AlN, AlON, or the like.

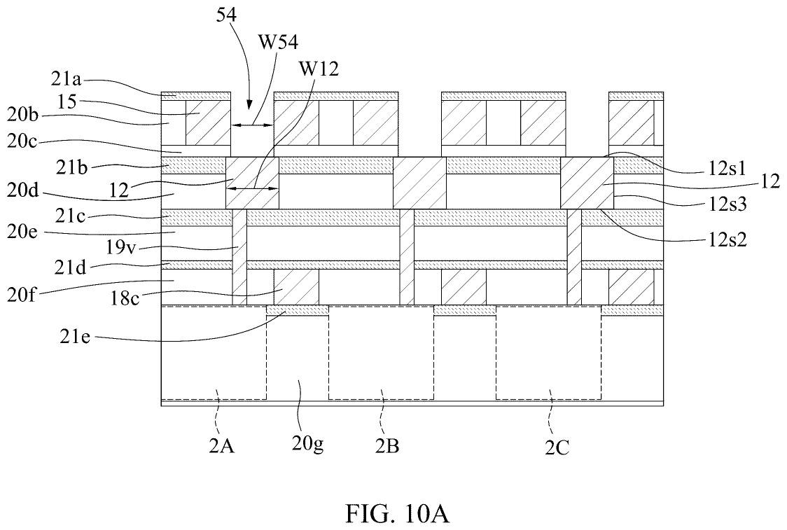

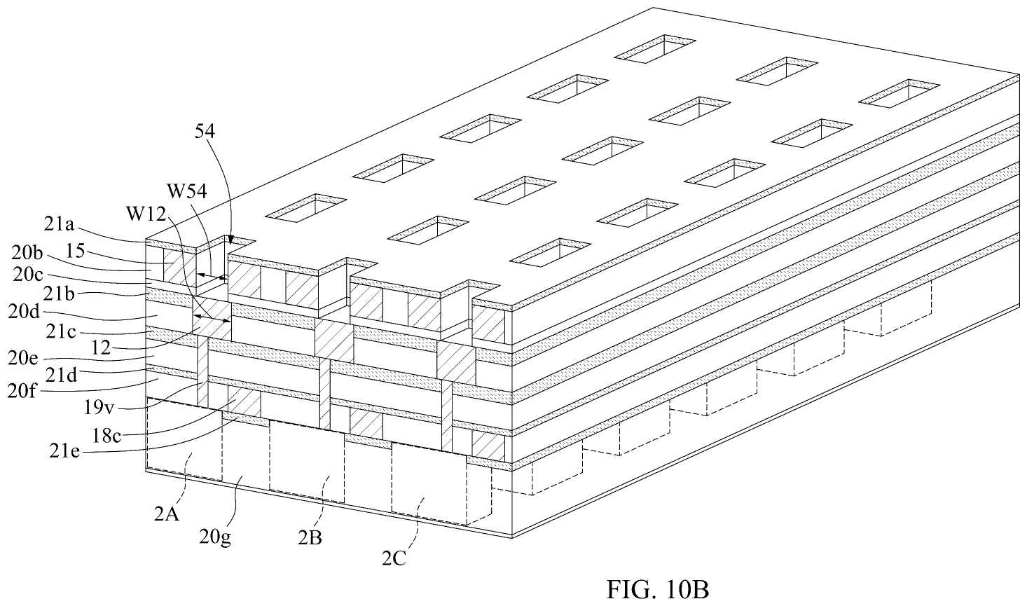

In FIGS. 10A and 10B, a passivation layer 21a is formed over the sacrificial layer 52, the gate electrode 15, and the insulating layer 20b. The passivation layer 21a can protect the gate electrode 15 from the following process (e.g., polishing process or etching process). A portion of the passivation layer 21a directly above the sacrificial layer 52 is removed to expose the sacrificial layer 52. The sacrificial layer 52 and/or a portion of the insulating layer 20c are removed to define a hole 54 over the source electrode 12. The source electrode 12 may be exposed by the hole 54. The hole 54 may have a width W54 smaller than a width W12 of the source electrode 12.

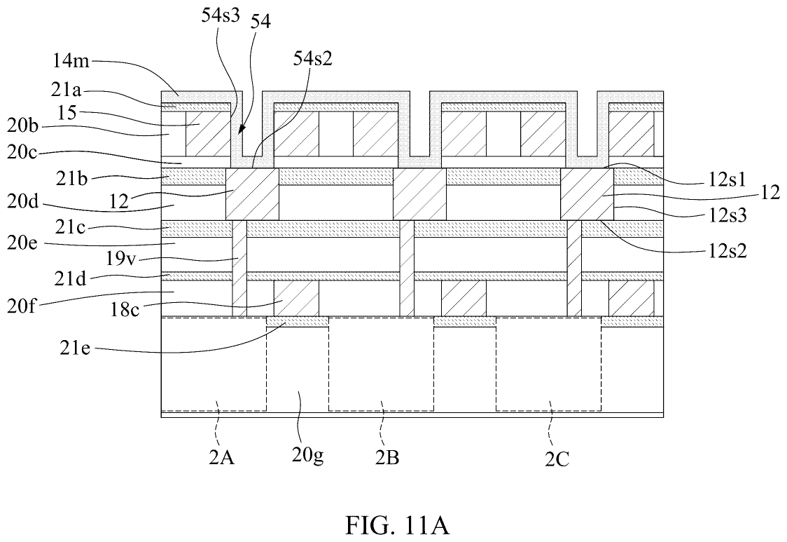

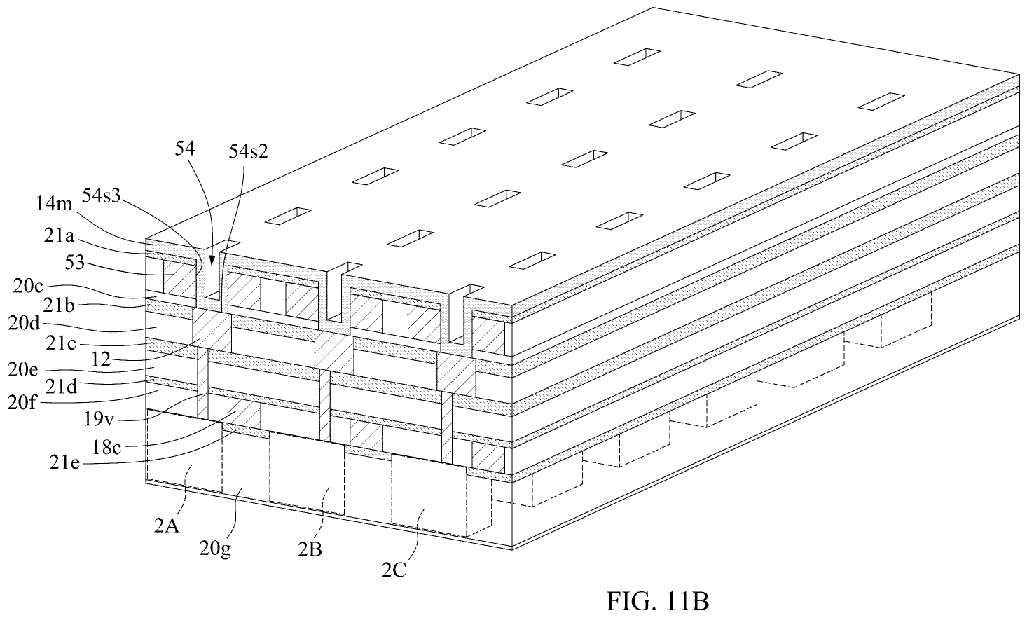

In FIGS. 11A and 11B, a gate dielectric layer material 14m is formed along a bottom surface 54s2 and a sidewall 54s3 of the hole 54. The gate dielectric layer material 14m is formed over the passivation layer 21a.

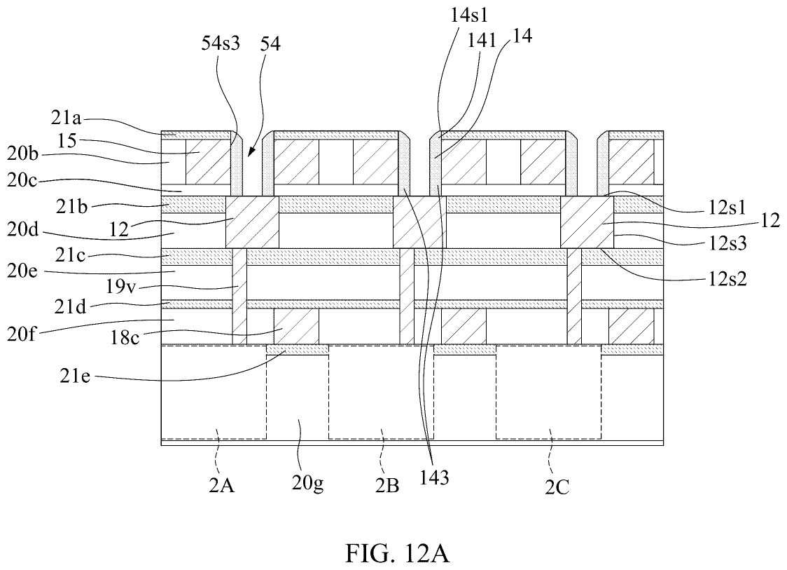

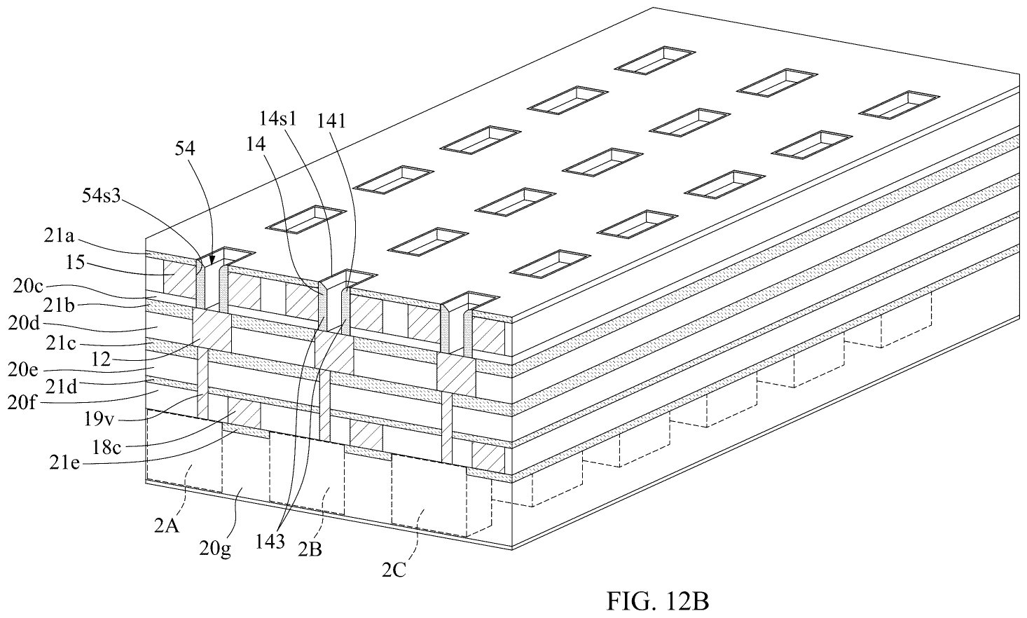

In FIGS. 12A and 12B, a portion of the gate dielectric layer material 14m over the passivation layer 21a and another portion of the gate dielectric layer material 14m on the bottom surface 54s2 of the hole 54 are removed by an etching process (e.g., isotropic etching). A portion of the gate dielectric layer material 14m along the sidewall 54s3 of the hole 54 is trimmed to form a gate dielectric layer 14. The gate dielectric layer 14 has a portion 141 adjacent to the passivation layer 21a. The portion 141 is tapered toward the passivation layer 21a. The portion 141 may have a width W14 that gradually decreases in a direction toward the passivation layer 21a (or in the Z direction). The gate dielectric layer 14 may have two lateral portions 143 disposed along the sidewall 54s3 of the hole 54.

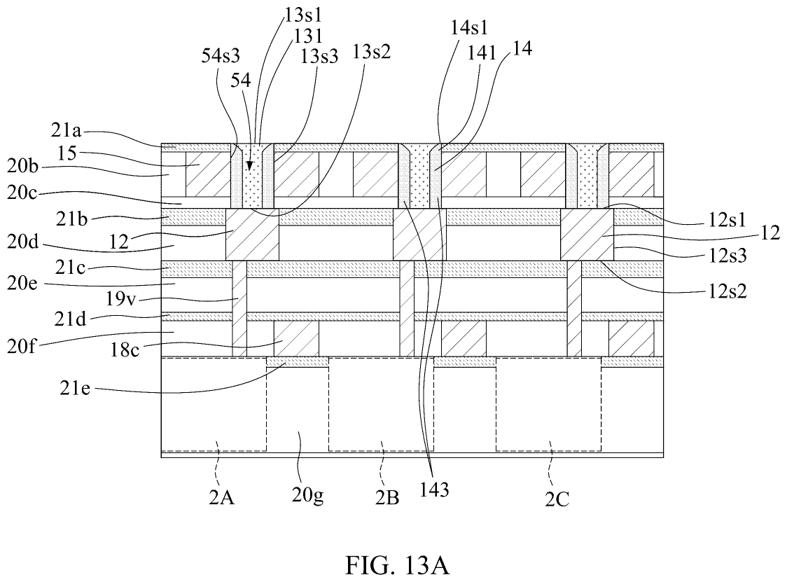

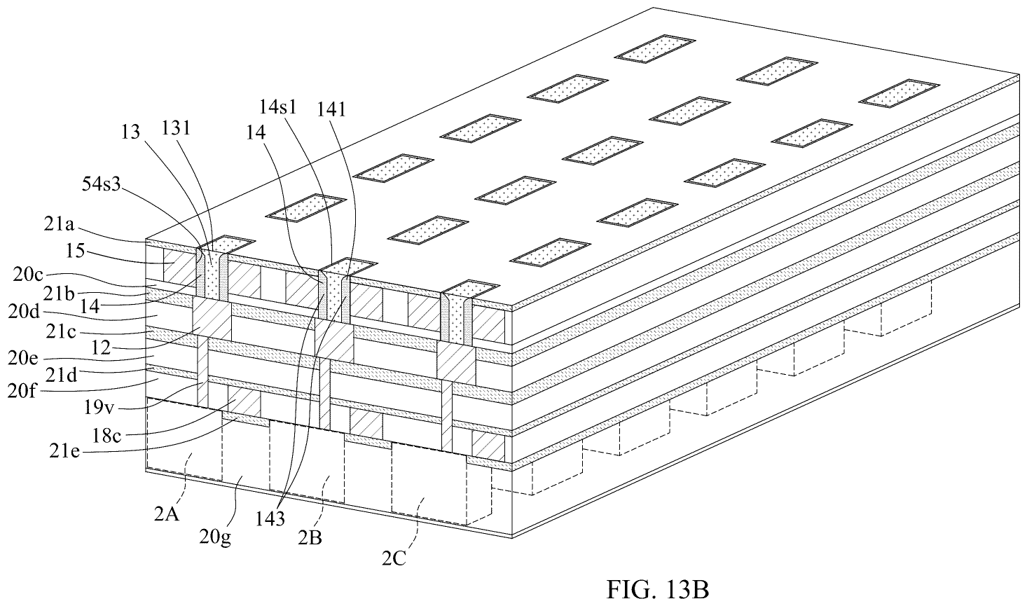

In FIGS. 13A and 13B, an oxide semiconductor layer 13 may be formed in the hole 54. The oxide semiconductor layer 13 may be formed by depositing an oxide semiconductor layer material over the passivation layer 21a and in the hole 54, and removing a portion of the oxide semiconductor layer material over the passivation layer 21a by a polishing process (e.g., chemical-mechanical polishing). A top surface 13s1 of the oxide semiconductor layer 13 and a top surface 14s1 of the gate dielectric layer 14 are at the same elevation or coplanar. A first height (or length) L13 of the oxide semiconductor layer 13 is greater than or equal to a second height (or length) L14 of the gate dielectric layer 14. Furthermore, the first height L13 of the oxide semiconductor layer 13 is greater than a third height (or length) L15 of the gate electrode 15. The oxide semiconductor layer missing effect can be prevented.

Owing to the taper shape of the portion 141 of the gate dielectric layer 14, the oxide semiconductor layer 13 may have a portion 131 with a funnel shape. The funnel shape has a long side exposed by the gate dielectric layer 14.

The gate electrode 15 is formed prior to the formation of the oxide semiconductor layer 13. The gate electrode 15 surrounds the sacrificial layer 52 which is then removed to define a region (or the hole 54), and the oxide semiconductor layer 13 is formed in the hole 54.

Furthermore, the oxide semiconductor layer 13 is formed within the hole 54 surrounded by the gate electrode 15. The oxide semiconductor layer 13 undergoes less damage than an oxide semiconductor layer formed by a blanket deposition of an oxide semiconductor material and subsequent etching. The defects of the oxide semiconductor layer 13 can be relatively few, and the quality thereof can be improved.

In some embodiments, the oxide semiconductor layer 13 may be void free. In some embodiments, the oxide semiconductor layer 13 may have a void when the aspect ratio of the hole 54 is relatively high.

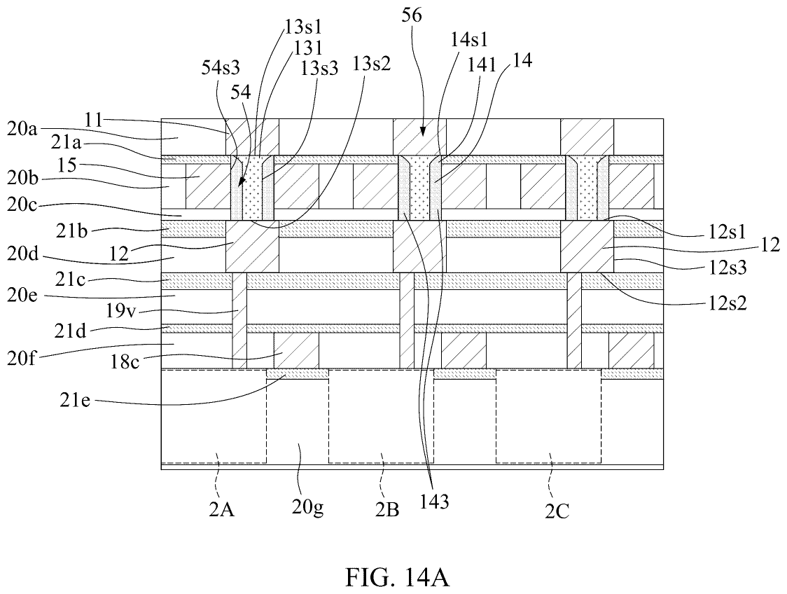

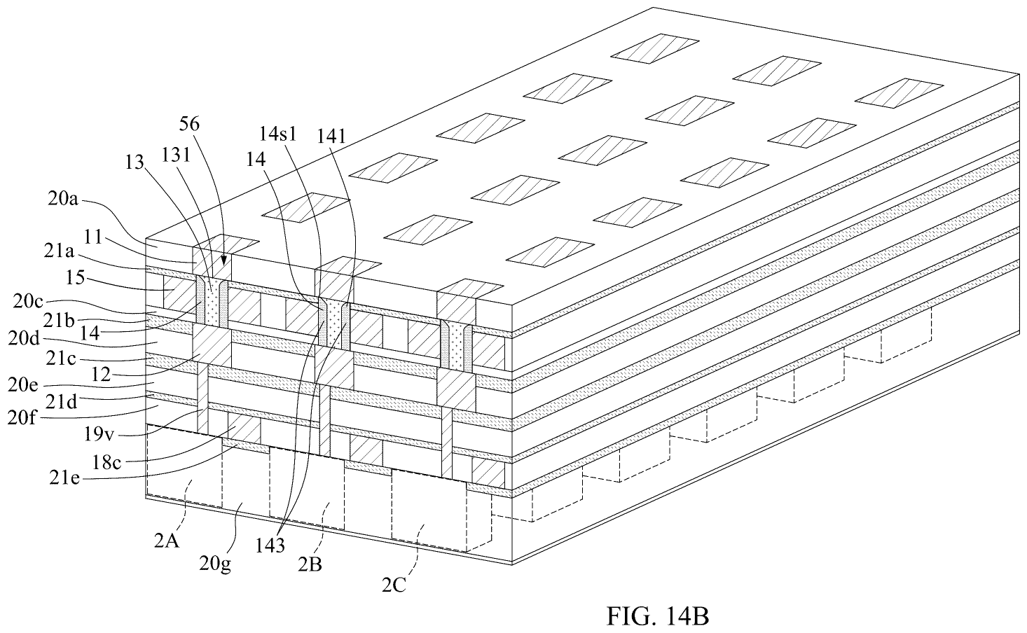

In FIGS. 14A and 14B, an insulating layer 20a is formed over the passivation layer 21a, the gate dielectric layer 14, and the oxide semiconductor layer 13. A portion of the insulating layer 20a over the gate dielectric layer 14 and the oxide semiconductor layer 13 is removed to define a hole 56. The gate dielectric layer 14 and the oxide semiconductor layer 13 are exposed by the hole 56. A drain electrode 11 is formed in the hole 56. The drain electrode 11 is in contact with the oxide semiconductor layer 13. The drain electrode 11 is in contact with the gate dielectric layer 14. In some embodiments, the drain electrode 11 may be free from contacting the gate dielectric layer 14 when the trimming in FIGS. 12A and 12B removes a relatively large amount of the gate dielectric layer material 14m.

In some embodiments, the top portion 131 is in contact with the drain electrode 11. A first elevation of the surface 13s1 of the oxide semiconductor layer 13 is higher than or identical to a second elevation of the surface 14s1 of the gate dielectric layer 14. An interface between the oxide semiconductor layer 13 and the drain electrode 11 and an interface between the gate dielectric layer 14 and the drain electrode 11 are coplanar.

In some embodiments, a conductive trace (e.g., the conductive trace 17) over the drain electrode is formed to complete the semiconductor device 100.

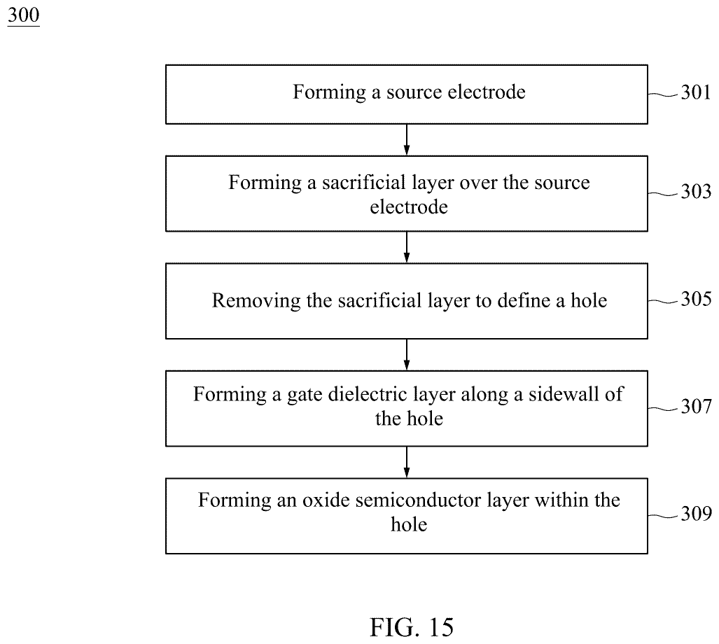

FIG. 15 is a flow diagram of a method 300 of manufacturing a semiconductor device in accordance with some embodiments of the present disclosure. The method 300 includes a number of operations (301, 303, 305, 307, and 309) and the description and illustration are not deemed as limitations to the sequence of the operations and the structure of the semiconductor memory device.

In operation 301, a source electrode (e.g., the source electrode 12) is formed. The source electrode may be formed over a passivation layer. An insulating layer and another passivation layer may be formed over the passivation layer in sequence. The insulating layer and the other passivation layer may be etched to have a plurality of holes, which are separated from each other. The source electrode may be formed in the holes. The operation 301 may correspond to the structure shown in FIGS. 7A and 7B.

In operation 303, a sacrificial layer (e.g., the sacrificial layer 52) is formed over the source electrode. The operation 303 may include forming a gate electrode (e.g., the gate electrode 15) over the source electrode prior to forming the gate dielectric layer. The gate electrode surrounds the sacrificial layer. The operation 303 may correspond to the structure shown in FIGS. 9A and 9B.

In operation 305, the sacrificial layer is removed to define a hole (e.g., the hole 54). A portion of an insulating layer 20c under the sacrificial layer may be removed to expose the source electrode. The operation 305 may correspond to the structure shown in FIGS. 10A and 10B.

In operation 307, a gate dielectric layer (e.g., the gate dielectric layer 14) is formed along a sidewall (e.g., the sidewall 54s3) of the hole. The operation 307 may include forming a gate dielectric layer material (e.g., the gate dielectric layer material 14m) over a bottom surface (e.g., the bottom surface 54s2) and the sidewall of the hole. A portion of the gate dielectric layer material over the bottom surface may be removed and another portion of the gate dielectric layer material along the sidewall may be trimmed to form the gate dielectric layer. The operation 307 may correspond to the structure shown in FIGS. 12A and 12B.

In operation 309, an oxide semiconductor layer (e.g., the oxide semiconductor layer 13) is within the hole. The operation 309 may correspond to the structure shown in FIGS. 13A and 13B.

The oxide semiconductor layer manufactured by the method 300 undergoes less damage than an oxide semiconductor layer formed by blanket deposition of an oxide semiconductor material and subsequent etching.

The method 300 may include forming a drain electrode (e.g., the drain electrode 11) over the gate dielectric layer and the oxide semiconductor layer and a conductive trace (e.g., the conductive trace 17) to form the semiconductor device 100. A first surface (e.g., the surface 13s1) of the oxide semiconductor layer and a second surface (e.g., the surface 14s1) of the gate dielectric layer are in contact with the drain electrode. In some embodiments, a first elevation of the first surface is higher than or identical to a second elevation of the second surface.

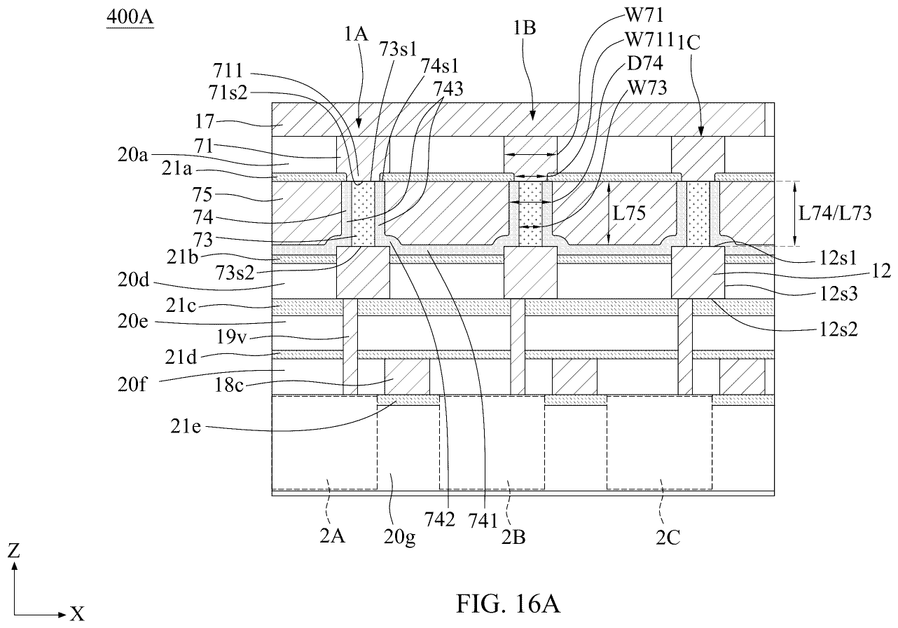

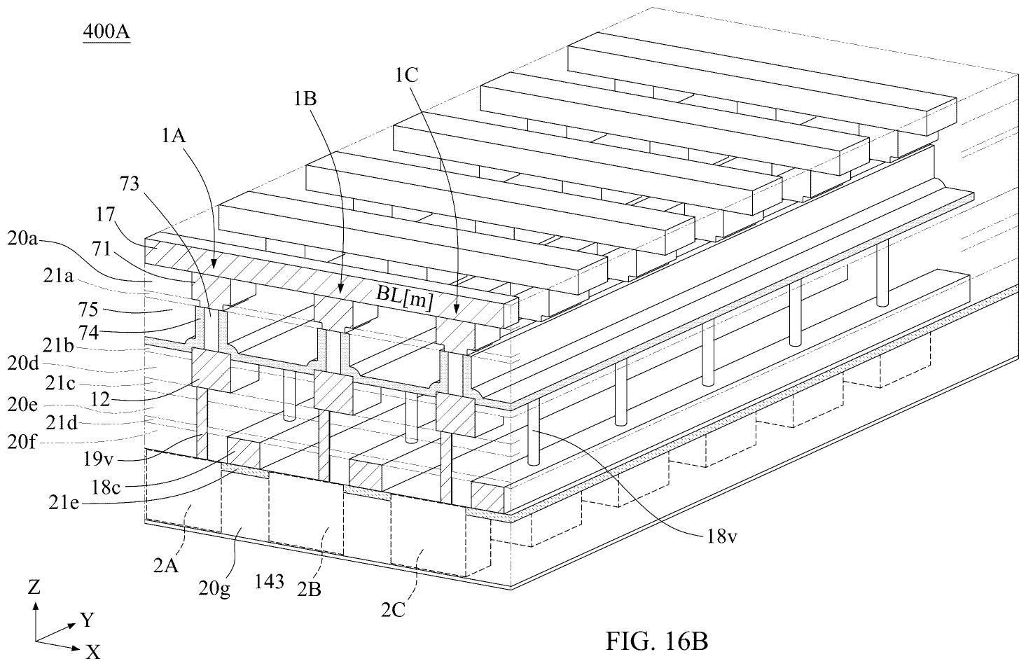

FIG. 16A is a cross-sectional view illustrating a semiconductor device 400A in accordance with some embodiments of the present disclosure. FIG. 16B is a schematic view illustrating the semiconductor device 400A in accordance with some embodiments of the present disclosure. The structure of the semiconductor device 400A is similar to the structure of the semiconductor device 100. Therefore, some detailed descriptions may refer to corresponding preceding paragraphs and are not repeated hereinafter for conciseness, with differences therebetween as follows.

The semiconductor device 400A includes a drain electrode 71, an oxide semiconductor layer 73, a gate dielectric layer 74, and a gate electrode 75, rather than the drain electrode 11, the oxide semiconductor layer 13, the gate dielectric layer 14, and the gate electrode 15. The materials of the drain electrode 71, the oxide semiconductor layer 73, the gate dielectric layer 74, and the gate electrode 75 are similar to those of the drain electrode 11, the oxide semiconductor layer 13, the gate dielectric layer 14, and the gate electrode 15, respectively.

The drain electrode 71 is surrounded by the insulating layer 20a. The drain electrode 71 is disposed below the conductive trace 17. The drain electrodes 71 of each of the transistors 1A, 1B, and 1C are connected to the conductive trace 17. The drain electrode 71 is disposed on the passivation layer 21a. The drain electrode 71 is disposed over the gate electrode 75, the oxide semiconductor layer 73, the gate dielectric layer 74, and/or the source electrode 12.

The drain electrode 71 has a bottom surface 71s2 facing the oxide semiconductor layer 73. In some embodiments, the bottom surface 71s2 may be in contact with the oxide semiconductor layer 73 and/or the gate dielectric layer 74. The drain electrode 71 may include a seed layer (not shown) disposed at the bottom surface 71s2 of the drain electrode 71.

The drain electrode 71 may have a portion 711 in contact with the oxide semiconductor layer 73 and the gate dielectric layer 74. The portion 711 is surrounded by the passivation layer 21a. The portion 711 may have a width W711 smaller than a width W71 of the main part of the drain electrode 71.

The gate electrodes 75 of each of the transistors 1A, 1B, and 1C may be dual gates. At least one part of the gate electrode 75 of each of the transistors 1A, 1B, and 1C is shared with an adjacent transistor. The gate electrode 75 is disposed over the insulating layer 20d. The gate electrode 75 is disposed below the passivation layer 21a. The gate electrode 75 is disposed between the drain electrode 71 and the source electrode 12 in the Z direction. The gate electrode 75 surrounds the gate dielectric layer 74 and/or the oxide semiconductor layer 73.

The gate dielectric layer 74 is in contact with the source electrode 12. The gate dielectric layer 74 is in contact with the drain electrode 11. The gate dielectric layer 74 is disposed below the drain electrode 71 and has a surface 74s1 in contact with the drain electrode 11. The gate dielectric layer 74 may have a portion 741 disposed below the gate electrode 75. The gate dielectric layer 74 has two lateral portions 743 from a cross-sectional view. The lateral portions 753 is in contact with the oxide semiconductor layer 73. A distance D74 between the two lateral portions 743 is smaller than a width W71 of the drain electrode 71. The distance D74 is greater than the width W711 of the portion 711 of the drain electrode 71. The lateral portions 743 may be in contact with the drain electrode 71 and the passivation layer 21a.

The gate dielectric layer 74 may have a portion 742 in contact with the top surface 12s1 and the lateral surface 12s3 of the source electrode 12. The portion 742 may have a rounded surface. The source electrode 12 may protrude from the passivation layer 21b. The portion 742 connects the portion 741 to the lateral portions 743.

The oxide semiconductor layer 73 is surrounded by the gate dielectric layer 74. The oxide semiconductor layer 73 may have a fin profile in the Y direction. In some embodiments, a channel region may be formed in the oxide semiconductor layers 73 in response to the voltage applied between the gate electrode 75 and the source electrode 12. Such a channel region connects the drain electrode 71 to the source electrode 12. A width W73 of the oxide semiconductor layer 73 is smaller than the width W711 of the portion 711 of the drain electrode 71.

The oxide semiconductor layers 73 of each of the transistors 1A, 1B, and 1C arranged along the X direction may be separated from each other. Furthermore, in the schematic view of FIG. 16B, the oxide semiconductor layers 73 of each of the transistors 1A, 1B, and 1C may be separated from other transistors arranged along the Y direction.

The oxide semiconductor layer 73 is disposed below the drain electrode 71 and has a surface (or a top surface) 73s1 in contact with the drain electrode 71. The oxide semiconductor layer 73 is disposed over the source electrode 12 and has a surface (or a bottom surface) 73s2 in contact with the source electrode 12. The oxide semiconductor layer 73 has a lateral surface 73s3 connecting the top surface 13s1 to the bottom surface 13s2. At least one of the lateral portions 743 of the gate dielectric layer 74 is in contact with the lateral surface 73s3 of the oxide semiconductor layer 73.

In the present disclosure, the gate electrode 75 is formed prior to the formation of the oxide semiconductor layer 73. The gate electrode 75 surrounds a sacrificial layer (e.g., the sacrificial layer 84) which is then removed to define a region (or the hole 86), and the oxide semiconductor layer 73 is formed in the hole. A first height (or length) L73 of the oxide semiconductor layer 73 is equal to a second height (or length) L74 of the gate dielectric layer 74. Furthermore, the first height L73 of the oxide semiconductor layer 73 is identical to a third height (or length) L75 of the gate electrode 75. The oxide semiconductor layer missing effect can be prevented.

In some embodiments, a first elevation of the surface 73s1 of the oxide semiconductor layer 73 is identical to a second elevation of the surface 74s1 of the gate dielectric layer 74. An interface between the oxide semiconductor layer 73 and the drain electrode 71 and an interface between the gate dielectric layer 74 and the drain electrode 71 are coplanar.

Furthermore, the oxide semiconductor layer 73 is formed within the hole surrounded by the gate electrode 75. The oxide semiconductor layer 73 has fewer defects than an oxide semiconductor layer formed by blanket deposition of an oxide semiconductor material and subsequent etching. The quality of oxide semiconductor layer 73 and the reliability of the semiconductor device 400A can be improved.

The transistor 1A may be included in the memory array 500 as shown in FIG. 1C. The semiconductor device 400A may include the memory elements 2A′, 2B′, and 2C′ of the FIG. 2. The semiconductor device 400A may include the memory elements 2A″, 2B″, and 2C″ of the FIG. 2.

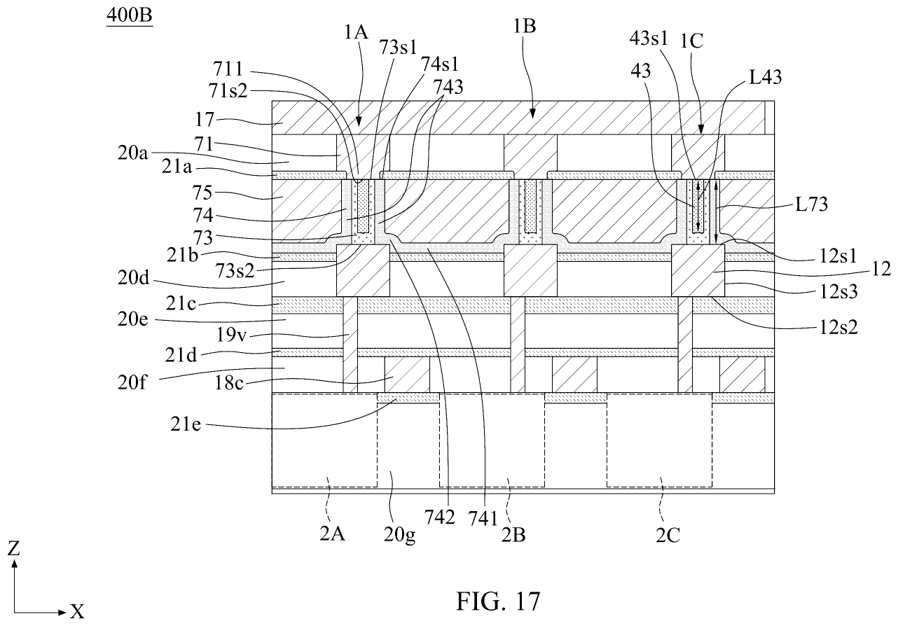

FIG. 17 is a cross-sectional view illustrating a semiconductor device in accordance with some embodiments of the present disclosure. The structure of the semiconductor device 400B is similar to the structure of the semiconductor device 400A. Therefore, some detailed descriptions may refer to corresponding preceding paragraphs and are not repeated hereinafter for conciseness, with differences therebetween as follows.

The semiconductor device 400B includes a second oxide semiconductor layer 43 surrounded by the oxide semiconductor layer 73. The second oxide semiconductor layer 43 has a short side 43s1 in contact with the drain electrode 71. The height L73 of the oxide semiconductor layer 73 is greater than a second height L43 of the second oxide semiconductor layer 43. The materials of the second oxide semiconductor layer 43 may be similar to those of the second oxide semiconductor layer 41.

A first doping concentration of the second oxide semiconductor layer 43 is smaller than a second doping concentration of the oxide semiconductor layer 73. The second oxide semiconductor layer 43 with lower doping concentration may increase the threshold voltage of the transistor 1A. The multiple oxide semiconductor layers 73 and 43 can reduce the charge traps formed at the interface between the gate dielectric layer 74 and the multiple oxide semiconductor layers 43 and 73. The second oxide semiconductor layer 43 can improve the negative bias temperature instability (NBTI) and/or the positive bias temperature instability (PBTI).

FIG. 17 shows two oxide semiconductor layers surrounded by the gate dielectric layer 74. However, embodiments of the present disclosure are not limited thereto. Many variations and/or modifications can be made to embodiments of the present disclosure. In some embodiments, the number of oxide semiconductor layers can be more than two.

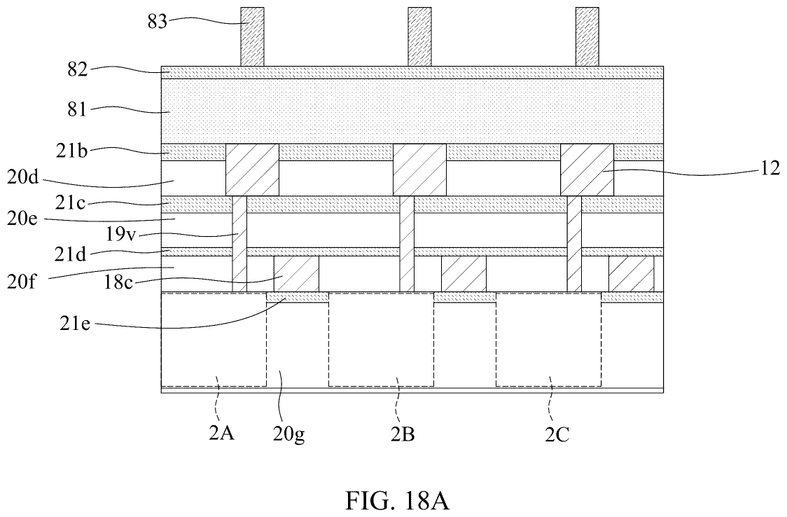

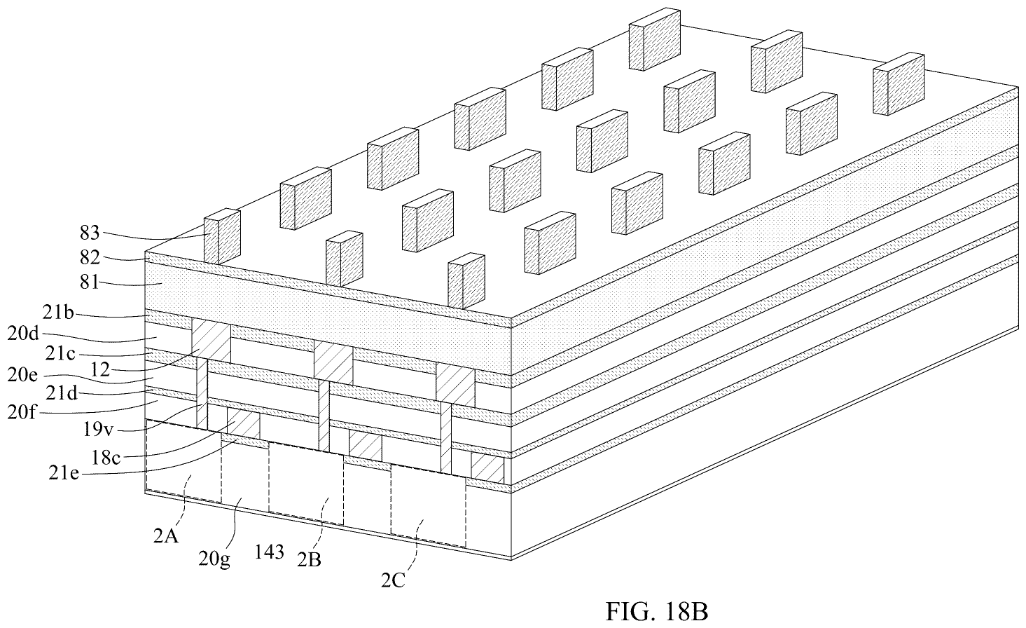

FIGS. 18A, 19A, 20A, 21A, 22A, 23A, 24A, and 25A are cross-sectional views of manufacturing a semiconductor device (e.g., the semiconductor device 400A) in accordance with some embodiments of the present disclosure. FIGS. 18B, 19B, 20B, 21B, 22B, 23B, 24B, and 25B are schematic views of manufacturing a semiconductor device (e.g., the semiconductor device 400A) in accordance with some embodiments of the present disclosure.

In FIGS. 18A to 25A and 18B to 25B, similar reference numerals will be assigned to corresponding portions described above, avoiding redundant descriptions. In addition, portions for which no particular description is made have constructions similar to those of semiconductor device 100 described above, and provide the same advantages.

The manufacturing of FIGS. 18A and 18B may follow the manufacturing of FIGS. 7A and 7B.

In FIGS. 18A and 18B, a sacrificial layer 81 and a passivation layer 82 are formed over the passivation layer 21b and the source electrode 12. A patterned photoresist 83 is formed over the passivation layer 82. The patterned photoresist 83 is substantially aligned with the source electrode 12.

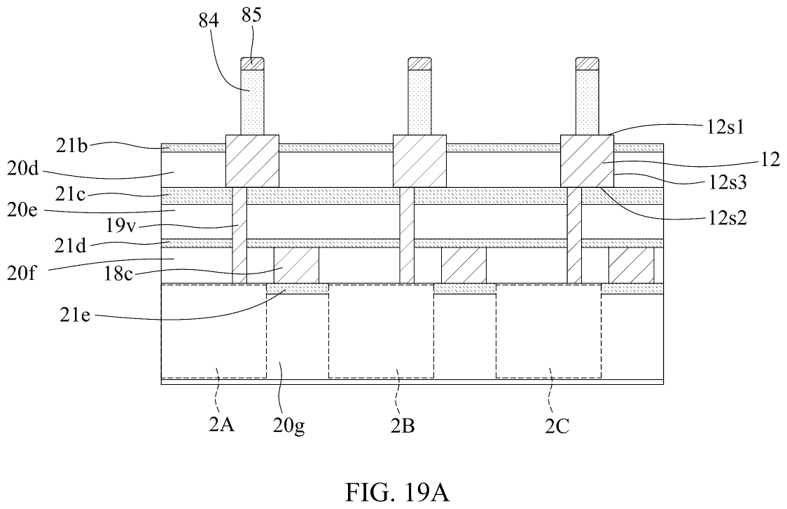

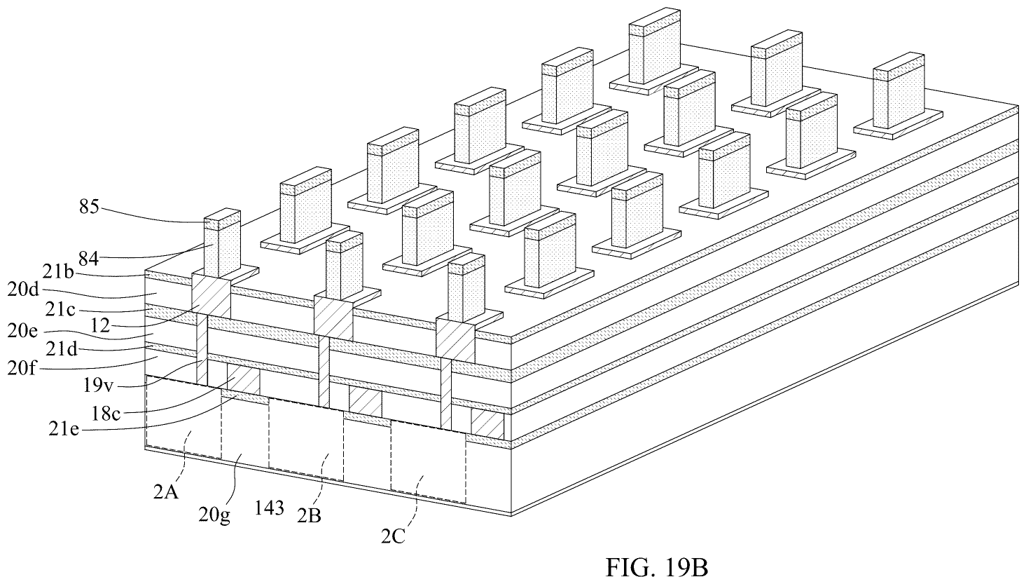

In FIGS. 19A and 19B, the sacrificial layer 81 and the passivation layer 82 may be etched with the patterned photoresist 83 to form a sacrificial layer 84 and a passivation layer 85 over the source electrode 12. The sacrificial layer 84 and the passivation layer 85 are substantially aligned with the source electrode 12. The source electrode 12 may protrude from the passivation layer 21b since the passivation layer 21b is also partially removed (i.e. thinned) during the etching process. The material of the sacrificial layers 81 and 84 may include SiN, SiCN, SiCON, AlN, AlON, or the like.

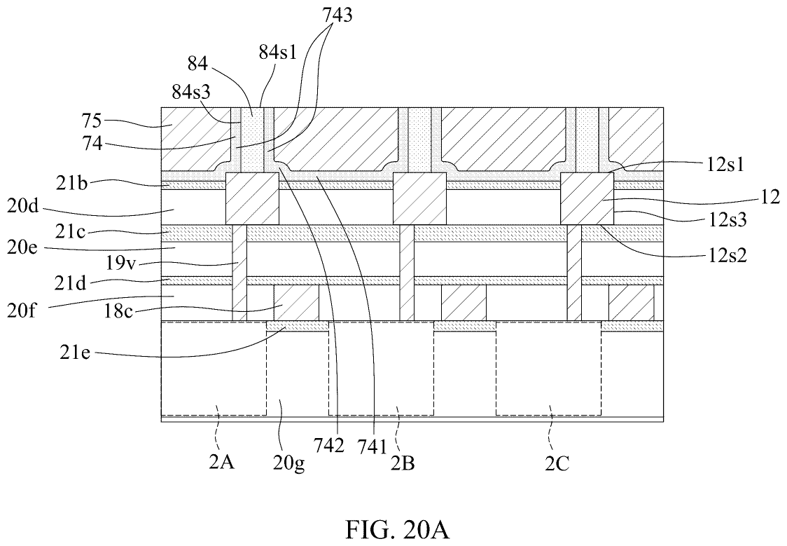

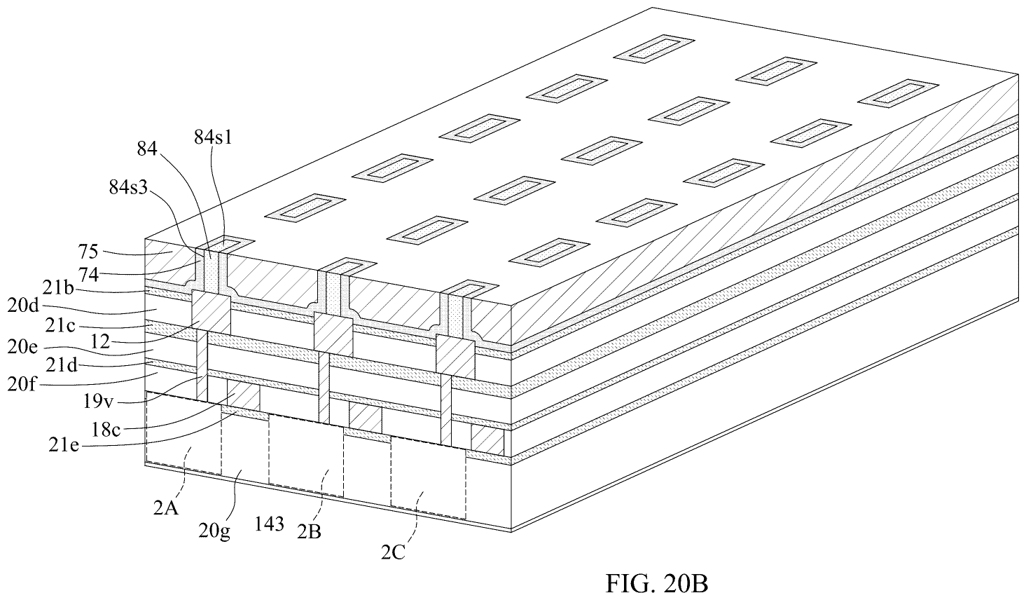

In FIGS. 20A and 20B, a gate dielectric layer 74 is formed to surround the sacrificial layer 84. The gate dielectric layer 74 may be formed over the passivation layer 21b. A gate electrode 75 is formed over the source electrode 12. The gate electrode 75 may surround the sacrificial layer 84. A top portion of the gate dielectric layer 74 may be removed to expose a top surface 84s1 of the sacrificial layer 84. In some embodiments, a gate dielectric layer material may be formed to cover the passivation layer 85, the sacrificial layer 84, and the passivation layer 21b. A gate electrode material may be formed to cover the gate dielectric layer material. The gate electrode material and the gate dielectric layer material are polished to form the gate electrode 75 and the gate dielectric layer 74. The passivation layer 85 may also be removed during the polishing process, and the top surface 84s1 of the sacrificial layer 84 may be exposed. The gate dielectric layer 74 may have a portion 741 over the passivation layer 21b, a lateral portion 743 along a lateral surface 84s3 of the sacrificial layer 84, and a portion 742 in contact with a top surface 12s1 and a lateral surface 12s3 of the source electrode 12.

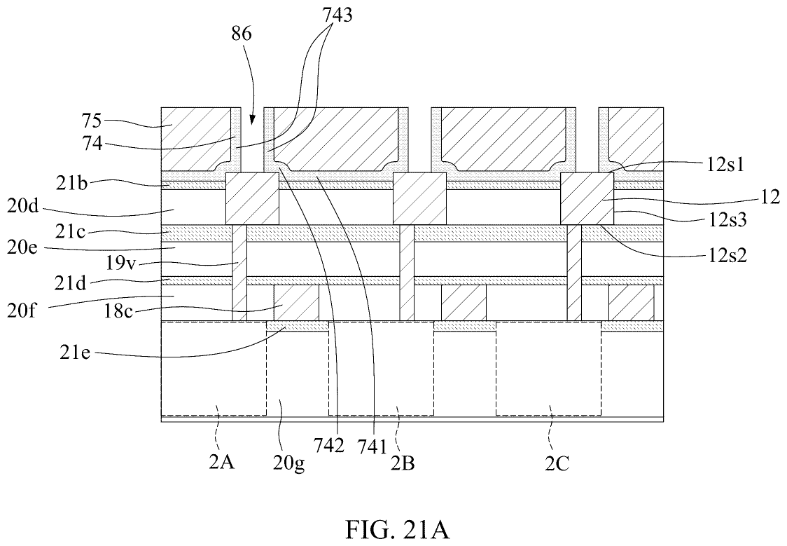

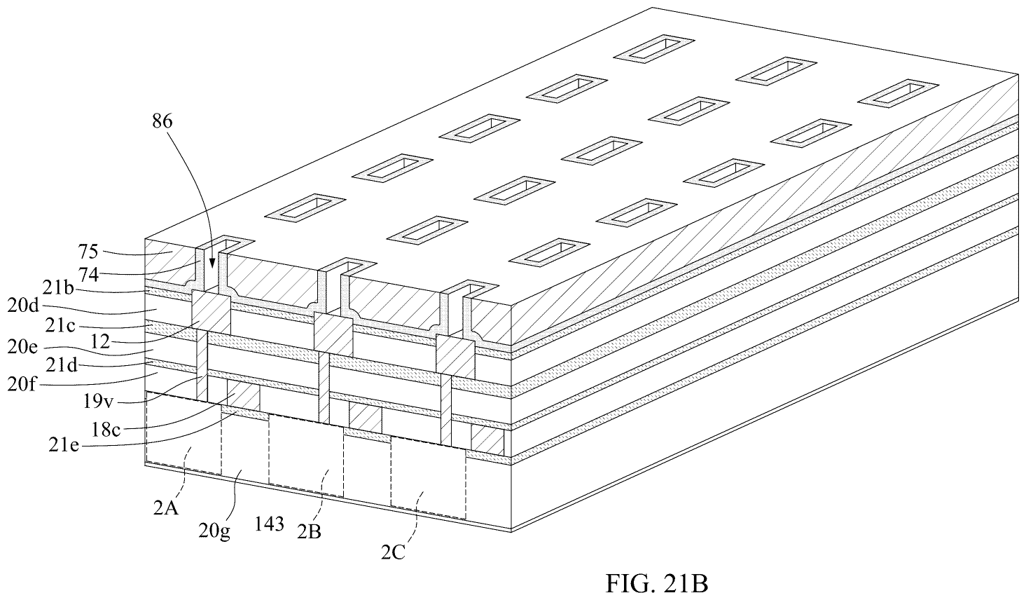

In FIGS. 21A and 21B, the sacrificial layer 84 is removed to define a hole 86. A portion of the top surface 12s1 of the source electrode 12 is exposed by the hole 86.

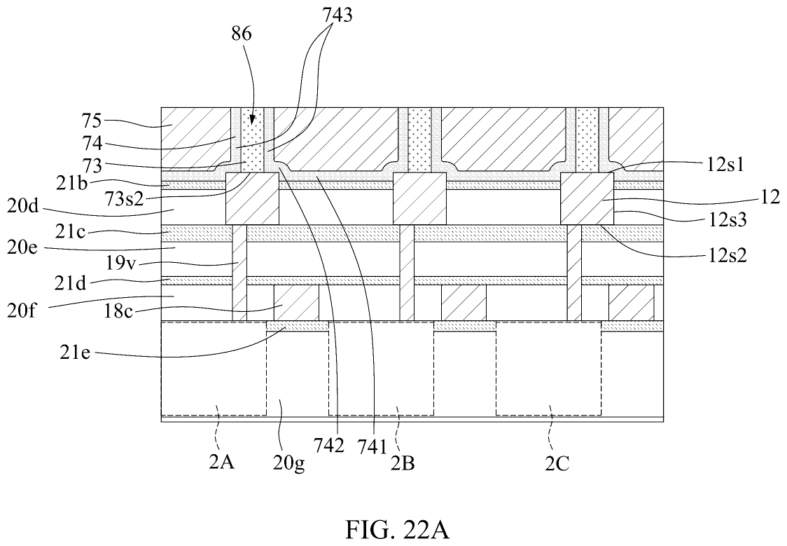

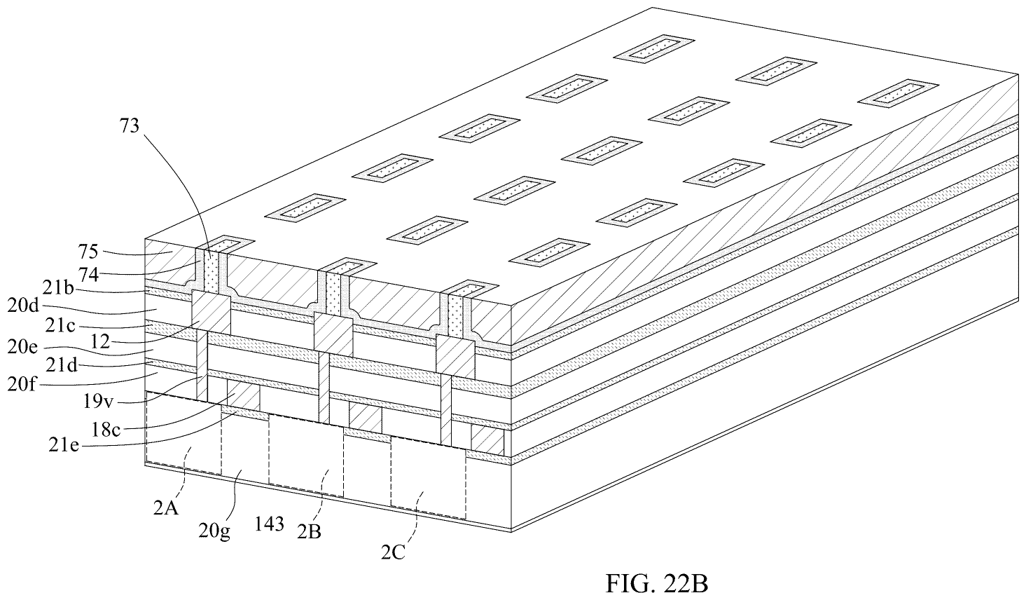

In FIGS. 22A and 22B, an oxide semiconductor layer 73 is formed in the hole 86. The oxide semiconductor layer 73 is surrounded by the gate dielectric layer 74. The oxide semiconductor layer 73 may be formed by depositing an oxide semiconductor layer material over the gate electrode 75 and in the hole 86, and removing a portion of the oxide semiconductor layer material over the gate electrode 75 by a polishing process (e.g., chemical-mechanical polishing). A first height (or length) L73 of the oxide semiconductor layer 73 is equal to a second height (or length) L74 of the gate dielectric layer 74. Furthermore, the first height L73 of the oxide semiconductor layer 73 is equal to a third height (or length) L75 of the gate electrode 75. The oxide semiconductor layer missing effect can be prevented.

The gate electrode 75 is formed prior to the formation of the oxide semiconductor layer 73. The gate electrode 75 surrounds the sacrificial layer 84 which is then removed to define a region (or the hole 86), and the oxide semiconductor layer 73 is formed in the hole 86. The oxide semiconductor layer 73 is formed within the hole 86 surrounded by the gate electrode 75. The oxide semiconductor layer 73 undergoes less damage than an oxide semiconductor layer formed by blanket deposition of an oxide semiconductor material and subsequent etching. The defects of the oxide semiconductor layer 73 can be relatively few, and the quality thereof can be improved.

In some embodiments, the oxide semiconductor layer 73 may be void free. In some embodiments, the oxide semiconductor layer 73 may have a void when the aspect ratio of the hole 86 is relatively high.

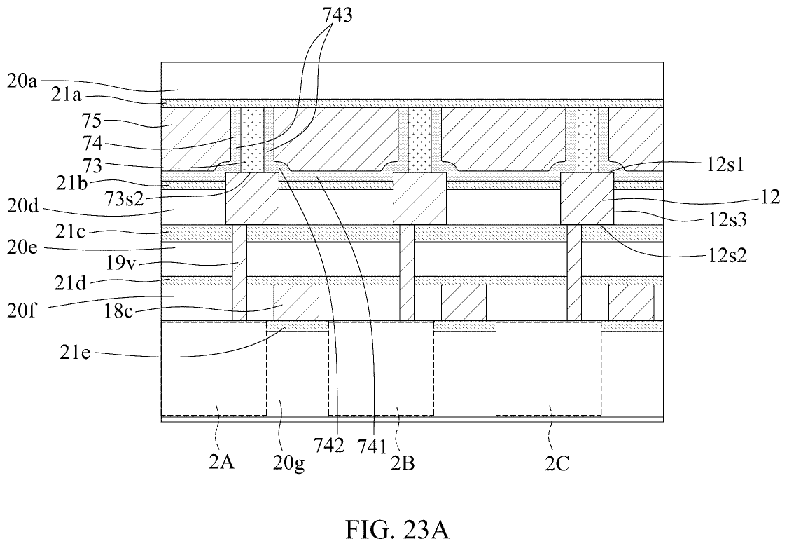

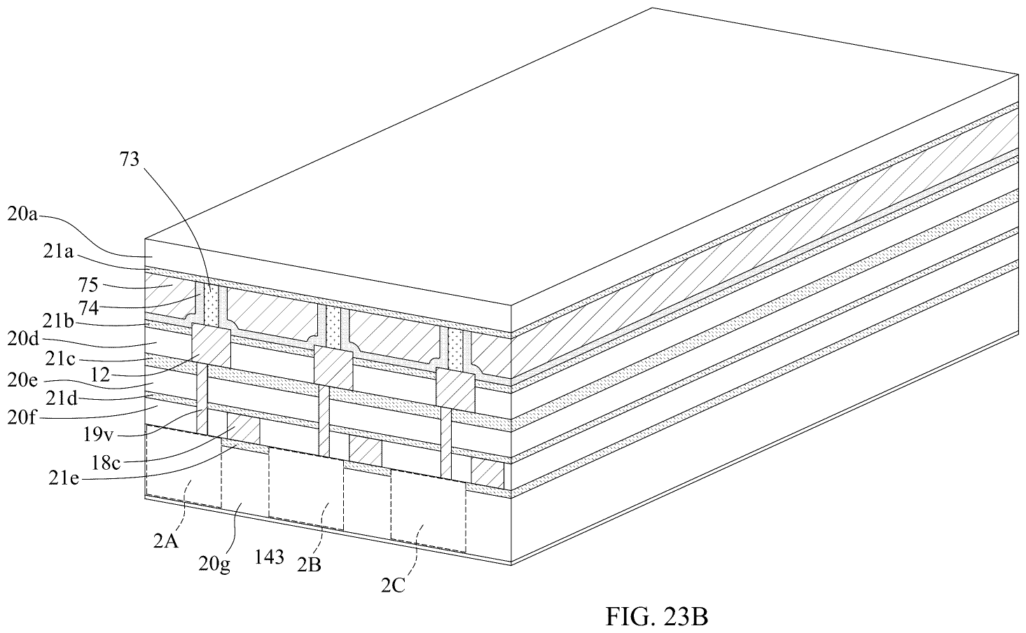

In FIGS. 23A and 23B, a passivation layer 21a and an insulating layer 20a are formed over the gate electrode 75, the gate dielectric layer 74, and the oxide semiconductor layer 73.

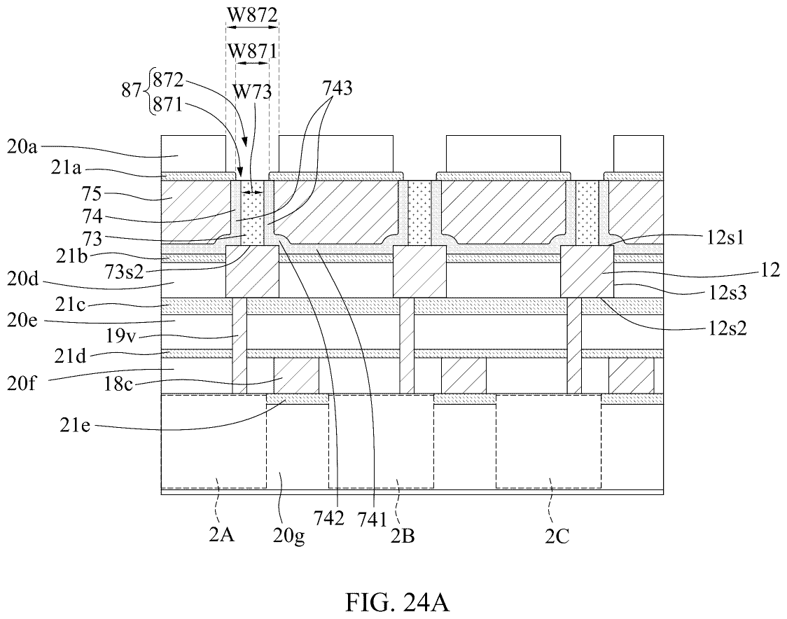

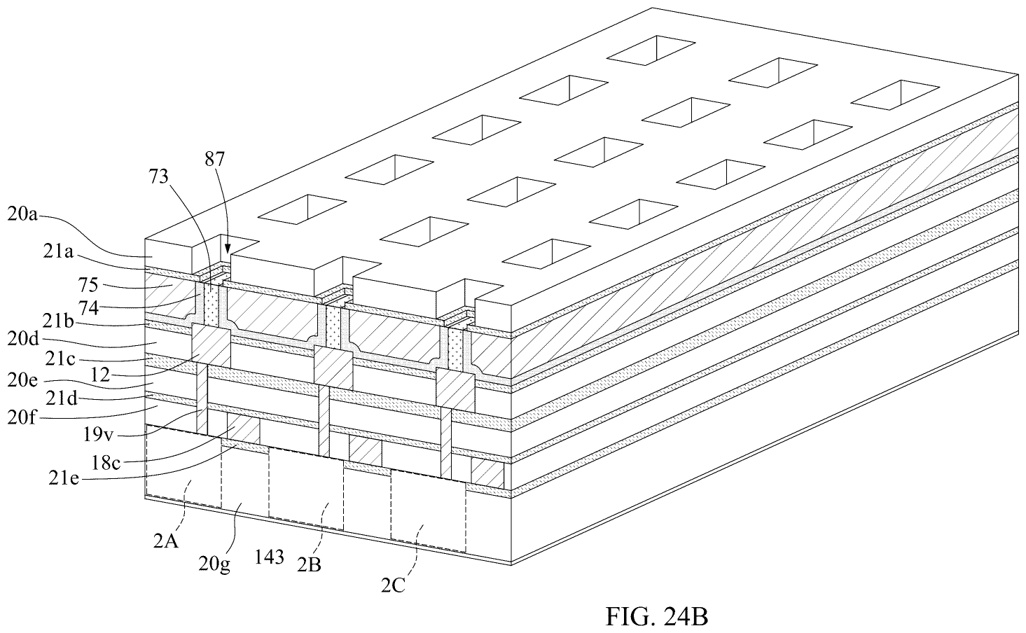

In FIGS. 24A and 24B, a portion of the insulating layer 20a and a portion of the passivation layer 21a over the gate dielectric layer 74 and the oxide semiconductor layer 73 are removed to define a hole 87. The hole 87 has a section 871 surrounded by the passivation layer 21a and a section 872 surrounded by the insulating layer 20a. A width W871 of the section 871 is smaller than a width W872 of the section 872. The width W871 is greater than a width W73 of the oxide semiconductor layer 73. The hole 87 with different widths (e.g., the width W871 and the width W872) may be formed by multiple patterning and etching processes. The hole 87 with different widths may be formed by an etching process with etchants that induce more lateral etching of the insulating layer 20a.

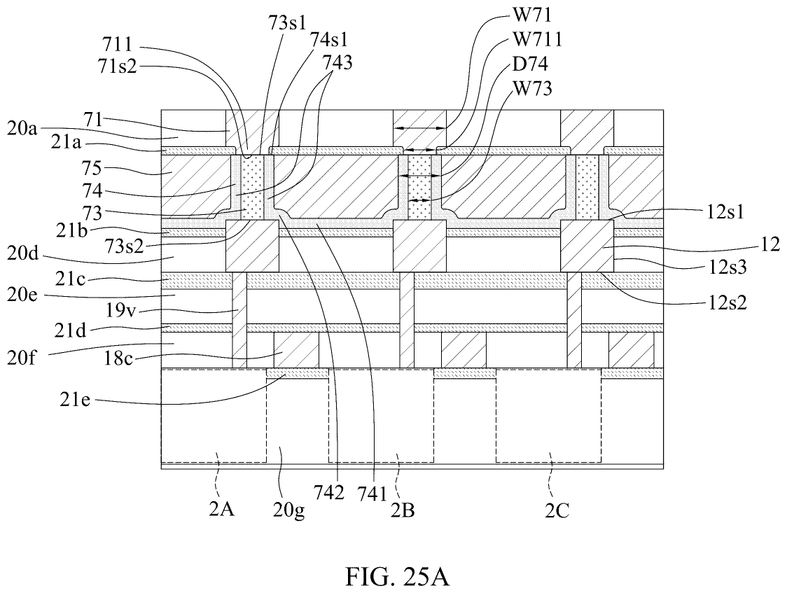

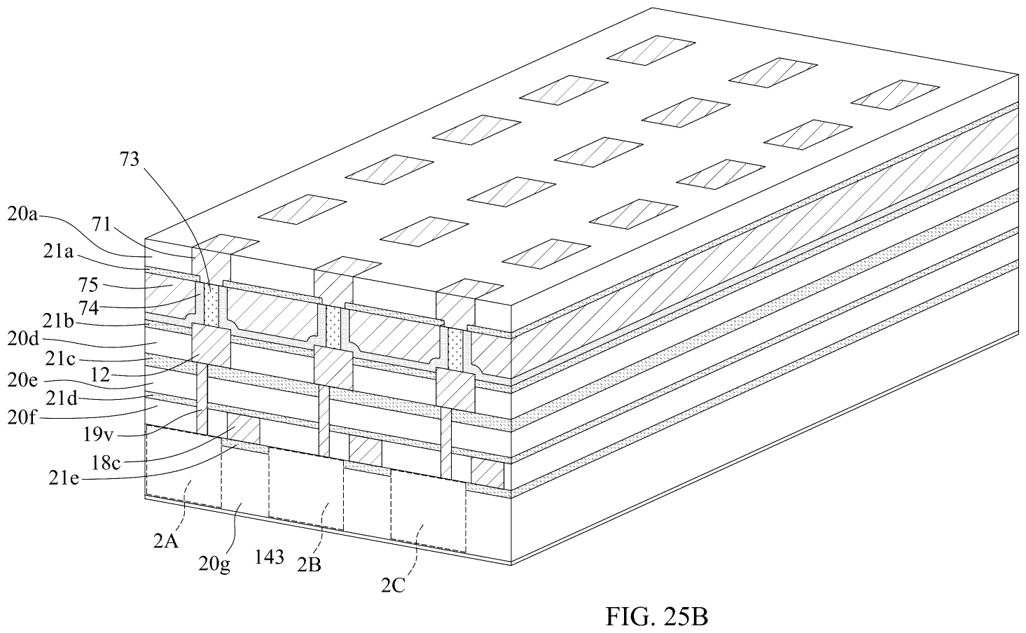

In FIGS. 25A and 25B, a drain electrode 71 is formed in the hole 87. The drain electrode 71 is in contact with the oxide semiconductor layer 73 and the gate dielectric layer 74. The protrusion of the passivation layer 21a may isolate the gate electrode 75 from the drain electrode 71. The drain electrode 71 may have a portion 711 in contact with the oxide semiconductor layer 73 and the gate dielectric layer 74. The portion 711 is formed in the section 871 of the hole 87. The portion 711 may have a width W711 smaller than a width W71 of the main part of the drain electrode 71. The width W711 is greater than a width W73 of the oxide semiconductor layer 73. The surface 73s1 of the oxide semiconductor layer 73 entirely connects to the drain electrode 72 to reduce the effective resistance therebetween. The width W711 is smaller than a distance D74 of the lateral portions 743.

In some embodiments, a conductive trace (e.g., the conductive trace 17) over the drain electrode is formed to complete the semiconductor device 400A.

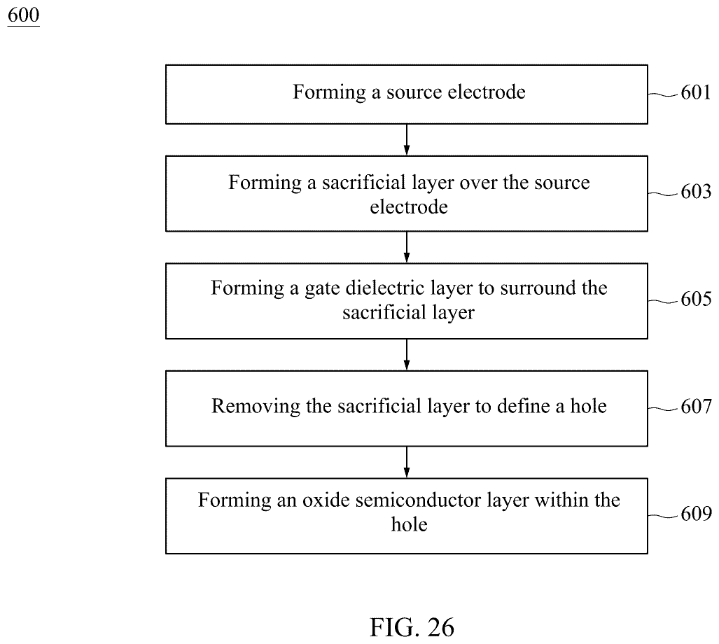

FIG. 26 is a flow diagram of a method 600 of manufacturing a semiconductor device in accordance with some embodiments of the present disclosure. The method 600 includes a number of operations (601, 606, 605, 607, and 609) and the description and illustration are not deemed as limitations to the sequence of the operations and the structure of the semiconductor memory device.

In operation 601, a source electrode (e.g., the source electrode 12) is formed. The operation 601 may be similar to the operation 301 of the method 300.

In operation 603, a sacrificial layer (e.g., the sacrificial layer 84) is formed over the source electrode. The operation 603 may correspond to the structure shown in FIGS. 19A and 19B.

In operation 605, a gate dielectric layer (e.g., the gate dielectric layer 74) is formed along a lateral surface (e.g., the lateral surface 84s3) of the sacrificial layer. A gate electrode (e.g., the gate electrode 75) may be concurrently formed. The operation 605 may correspond to the structure shown in FIGS. 20A and 20B.

In operation 607, the sacrificial layer is removed to define a hole (e.g., the hole 54). The operation 607 may correspond to the structure shown in FIGS. 21A and 21B.

In operation 609, an oxide semiconductor layer (e.g., the oxide semiconductor layer 73) is formed within the hole. The operation 609 may correspond to the structure shown in FIGS. 22A and 22B.

The oxide semiconductor layer manufactured by the method 600 undergoes less damage than an oxide semiconductor layer formed by blanket deposition of an oxide semiconductor material and subsequent etching.

The method 600 may include forming a drain electrode (e.g., the drain electrode 71) over the gate dielectric layer and the oxide semiconductor layer and a conductive trace (e.g., the conductive trace 17) to form the semiconductor device 400A. A first surface (e.g., the surface 73s1) of the oxide semiconductor layer and a second surface (e.g., the surface 74s1) of the gate dielectric layer are in contact with the drain electrode. In some embodiments, a first elevation of the first surface is higher than or identical to a second elevation of the second surface.

According to other embodiments, a semiconductor device is provided. The semiconductor device includes a drain electrode, a first oxide semiconductor layer, and a gate dielectric layer. The first oxide semiconductor layer is disposed below the drain electrode and has a first surface in contact with the drain electrode. The gate dielectric layer is disposed below the drain electrode and has a second surface in contact with the drain electrode. A first elevation of the first surface is higher than or identical to a second elevation of the second surface.

According to other embodiments, a method of manufacturing a semiconductor device is provided. The method includes forming a source electrode; forming a sacrificial layer over the source electrode; removing the sacrificial layer to define a hole; forming a gate dielectric layer along a sidewall of the hole; and forming an oxide semiconductor layer within the hole.

According to other embodiments, a method of manufacturing a semiconductor device is provided. The method includes: forming a source electrode; forming a sacrificial layer over the source electrode; forming a gate dielectric layer to surround the sacrificial layer; removing the sacrificial layer to define a hole; and forming an oxide semiconductor layer within the hole.

The methods and features of the present disclosure have been sufficiently described in the above examples and descriptions. It should be understood that any modifications or changes without departing from the spirit of the present disclosure are intended to be covered in the protection scope of the present disclosure.

Moreover, the scope of the present application in not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, may be utilized according to the present disclosure.

Accordingly, the appended claims are intended to include within their scope: processes, machines, manufacture, and compositions of matter, means, methods or steps. In addition, each claim constitutes a separate embodiment, and the combination of various claims and embodiments are within the scope of the present disclosure.

What is claimed is:

1. A semiconductor device, comprising:
a drain electrode;
a first oxide semiconductor layer disposed below the drain electrode and having a first surface in contact with the drain electrode; and
a gate dielectric layer disposed below the drain electrode and having a second surface in contact with the drain electrode,
wherein a first elevation of the first surface is higher than or identical to a second elevation of the second surface.

2. The semiconductor device of claim 1, wherein the first oxide semiconductor layer has a top portion in contact with the drain electrode, and the top portion has a funnel shape.

3. The semiconductor device of claim 2, wherein the gate dielectric layer has a portion surrounding the top portion of the first oxide semiconductor layer, wherein the portion of the gate dielectric layer is tapered toward the drain electrode.

4. The semiconductor device of claim 1, further comprising a source electrode disposed below a bottom surface of the first oxide semiconductor layer, wherein a first width of the first surface is larger than a second width of the bottom surface.

5. The semiconductor device of claim 1, further comprising a source electrode disposed below the gate dielectric layer, wherein a top surface and a lateral surface of the source electrode are in contact with the gate dielectric layer.

6. The semiconductor device of claim 5, further comprising a passivation layer disposed below the gate dielectric layer, wherein the source electrode protrudes from the passivation layer.

7. The semiconductor device of claim 1, further comprising a transistor and a memory element connected to the transistor, wherein the transistor comprises the gate dielectric layer, the drain electrode, and the first oxide semiconductor layer.

8. The semiconductor device of claim 1, further comprising a second oxide semiconductor layer surrounded by the first oxide semiconductor layer, wherein a first doping concentration of the second oxide semiconductor layer is smaller than a second doping concentration of the first oxide semiconductor layer.

9. The semiconductor device of claim 8, wherein the second oxide semiconductor layer has a short side in contact with the drain electrode.

10. The semiconductor device of claim 8, wherein a first height of the first oxide semiconductor layer is greater than a second height of the second oxide semiconductor layer.

11. The semiconductor device of claim 1, wherein a first height of the first oxide semiconductor layer is higher than or equal to a second height of the gate dielectric layer.

12. The semiconductor device of claim 1, wherein the first oxide semiconductor layer is surrounded by the gate dielectric layer and the gate dielectric layer has two lateral portions from a cross-sectional view, wherein a distance between the two lateral portions is smaller than a width of the drain electrode.

13. The semiconductor device of claim 1, wherein the gate dielectric layer has a lateral portion in contact with a lateral surface of the first oxide semiconductor layer, wherein the lateral portion has multiple thicknesses.

14. A method of manufacturing a semiconductor device, comprising:
forming a source electrode;
forming a sacrificial layer over the source electrode;
removing the sacrificial layer to define a hole;
forming a gate dielectric layer along a sidewall of the hole; and
forming an oxide semiconductor layer within the hole.

15. The method of claim 14, further comprising forming a gate electrode over the source electrode prior to forming the gate dielectric layer.

16. The method of claim 14, further comprising forming a drain electrode over the gate dielectric layer and the oxide semiconductor layer, wherein a first surface of the oxide semiconductor layer and a second surface of the gate dielectric layer are in contact with the drain electrode.

17. The method of claim 16, wherein a first elevation of the first surface is higher than or identical to a second elevation of the second surface.

18. A method of manufacturing a semiconductor device, comprising:
forming a source electrode;
forming a sacrificial layer over the source electrode;
forming a gate dielectric layer to surround the sacrificial layer;
removing the sacrificial layer to define a hole; and
forming an oxide semiconductor layer within the hole.

19. The method of claim 18, further comprising forming a gate electrode over the source electrode prior to forming the oxide semiconductor layer.

20. The method of claim 18, further comprising removing a top portion of the gate dielectric layer to expose a top surface of the sacrificial layer.
